(19) United States
(12) Patent Application Publication
(10) Pub. No.: US 2025/0337235 A1
(43) Pub. Date: Oct. 30, 2025

(54) HOME APPLIANCE COMPRISING POWER CONVERTER EMPLOYING OVERHEATING PREVENTION METHOD

(71) Applicant: Samsung Electronics Co., Ltd., Suwon-si (KR)

(72) Inventors: Kwangil RYU, Suwon-si (KR); Sejin SOHN, Suwon-si (KR); Mirye SONG, Suwon-si (KR); Wonseo JANG, Suwon-si (KR); Jinseob JEON, Suwon-si (KR); Sejin JO, Suwon-si (KR)

(21) Appl. No.: 19/262,927

(22) Filed: Jul. 8, 2025

Related U.S. Application Data
(63) Continuation of application No. PCT/KR2024/001351, filed on Jan. 29, 2024.

(30) Foreign Application Priority Data
Mar. 22, 2023 (KR) 10-2023-0037540
Jun. 23, 2023 (KR) 10-2023-0081340

(51) Int. Cl. H02H 7/18; A47L 9/28; G01K 1/02; G01K 1/024; G01K 3/00; G01K 7/22; H02H 1/00

(52) U.S. Cl. CPC H02H 7/18; A47L 9/2805; A47L 9/2857; A47L 9/2889; G01K 1/024; G01K 1/026; G01K 3/005; G01K 7/22; H02H 1/0007

(57) ABSTRACT

A home appliance is provided. The home appliance includes a direct current (DC) link capacitor configured to smooth an alternating current input voltage, at least one divider resistor configured to divide a voltage across the DC link capacitor, a first temperature sensor connected in series to the at least one divider resistor, and configured to, together with the at least one divider resistor, divide the voltage across the DC link capacitor, wherein a resistance of the first temperature sensor changes according to a temperature, a pulse-width modulation (PWM) controller configured to determine whether overheating has occurred, based on a change in a voltage between a first point and a ground, wherein the first point is a connection point between the at least one divider resistor and the first temperature sensor, and serves as an input to the PWM controller, a switch whose switching is cut off by the PWM controller in response to the PWM controller determining that the overheating has occurred, and a transformer configured to convert an output alternating current voltage generated according to a switching operation of the switch.

### CROSS-REFERENCE TO RELATED APPLICATION(S)

This application is a continuation application, claiming priority under 35 U.S.C. § 365(c), of an International application No. PCT/KR2024/001351, filed on Jan. 29, 2024, which is based on and claims the benefit of a Korean patent application number 10-2023-0037540, filed on Mar. 22, 2023, in the Korean Intellectual Property Office, and of a Korean patent application number 10-2023-0081340, filed on Jun. 23, 2023, in the Korean Intellectual Property Office, the disclosure of each of which is incorporated by reference herein in its entirety.

### BACKGROUND

### 1. Field

The disclosure relates to a method of preventing overheating in a battery-powered cleaner device, and a cleaner device employing the method.

### 2. Description of Related Art

A home appliance may convert an alternating current input voltage into direct current voltages of various levels by using a switched-mode power supply (SMPS) that is a power conversion device, in order to use direct current voltages. The direct current voltage may be used, for example, to charge a battery included in the home appliance.

A cordless cleaner is an example of such a home appliance. A cordless cleaner is a type of cleaner that uses a built-in rechargeable battery, eliminating the need to connect a cord to an outlet during use. A cordless cleaner may include a suction motor that generates suction force, and by using the suction force generated by the suction motor, the cordless cleaner may draw in foreign substances such as dust along with air from a cleaner head (brush), separate the foreign substances from the air, and collect the dust.

Compared to corded cleaners, cordless cleaners are significantly convenient to use because they do not require plugging in with a power cord. Consequently, cordless cleaners have become popular. Meanwhile, usage patterns for cordless cleaners have diversified according to user and environmental conditions. Recently, with the introduction of cordless cleaners designed to couple with a station (dust discharger) that automatically empties a dust container attached to a main body of the cordless cleaner upon docking, the usage patterns, methods, and structures of cleaners have become highly diverse.

Here, the main body of the cordless cleaner is powered by a battery without a power cord. A cleaner main body may provide various display functions in addition to a cleaning function, in which case, continuous battery charging is necessary. Furthermore, a power conversion device, such as an SMPS, is necessary for battery charging. When overheating occurs in the cleaner during battery charging/discharging or a cleaning operation, a protection function is needed to prevent components of the cleaner device from being damaged by the overheating.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a method of preventing overheating in a battery-powered cleaner device, and a cleaner device employing the method.

Additional aspects will be set forth in part in the description which follows and, in part, will be apparent from the description, or may be learned by practice of the presented embodiments.

In accordance with an aspect of the disclosure, a home appliance is provided. The home appliance includes a direct current (DC) link capacitor configured to smooth an alternating current input voltage, at least one divider resistor configured to divide a voltage across the DC link capacitor, a first temperature sensor connected in series to the at least one divider resistor, and configured to, together with the at least one divider resistor, divide the voltage across the DC link capacitor, wherein a resistance of the first temperature sensor changes according to a temperature, a pulse-width modulation (PWM) controller configured to determine whether overheating has occurred, based on a change in a voltage between a first point and a ground, wherein the first point is a connection point between the at least one divider resistor and the first temperature sensor, and serves as an input to the PWM controller, a switch whose switching is cut off by the PWM controller in response to the PWM controller determining that the overheating has occurred, and a transformer configured to convert an output alternating current voltage generated according to a switching operation of the switch.

In accordance with another aspect of the disclosure, a method of preventing overheating by using a temperature sensor in a home appliance is provided. The method includes generating a DC voltage by rectifying an alternating current input voltage, and generating, from the generated DC voltage, a DC voltage smoothed by a DC link capacitor. The method of preventing overheating by a temperature sensor in a home appliance, according to an embodiment of the disclosure, includes sensing, by a PWM controller, from a temperature sensing circuit that includes a divider resistor for dividing the smoothed DC voltage and the temperature sensor, a voltage corresponding to a change in a resistance of the temperature sensor according to a change in a temperature in a vicinity of the temperature sensor. The method of preventing overheating by a temperature sensor in a home appliance, according to an embodiment of the disclosure, includes, in response to a magnitude of the sensed voltage reaching a predetermined threshold voltage, cutting off, by the PWM controller, driving of a switch for overheating prevention.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 a diagram illustrating a cordless cleaner device, which is a type of home appliance including a combination of a station and a cleaner main body, according to an embodiment of the disclosure;

FIG. 2 is a diagram for describing a station and a cleaner main body, according to an embodiment of the disclosure;

FIG. 3 is a configuration diagram of a cordless cleaner using a battery, according to an embodiment of the disclosure;

FIG. 4 is a block diagram of a cordless cleaner according to an embodiment of the disclosure;

FIG. 5 is a block diagram of a switched-mode power supply (SMPS) according to an embodiment of the disclosure;

FIG. 6 is a circuit diagram in which a temperature sensing circuit is connected to a feedback signal side of a pulse-width modulation (PWM) controller according to an embodiment of the disclosure;

FIG. 7A is a characteristic curve graph of a thermistor as a temperature sensor used in a temperature sensing circuit, according to an embodiment of the disclosure;

FIG. 7B is a characteristic curve graph of a thermistor as a temperature sensor used in a temperature sensing circuit, according to an embodiment of the disclosure;

FIG. 8 is a configuration diagram of an SMPS including a temperature sensing circuit, according to an embodiment of the disclosure;

FIG. 9 is a configuration diagram of an SMPS including a temperature sensing circuit, according to an embodiment of the disclosure;

FIG. 10 is a configuration diagram of an SMPS including a temperature sensing circuit, according to an embodiment of the disclosure;

FIG. 11 is a configuration diagram of an SMPS including a temperature sensing circuit, according to an embodiment of the disclosure;

FIG. 12 is a configuration diagram of an SMPS including a temperature sensing circuit, according to an embodiment of the disclosure;

FIG. 13 is a configuration diagram of an SMPS including a temperature sensing circuit, according to an embodiment of the disclosure;

FIG. 14A is a block diagram for detecting a position of an overheating occurrence in a temperature sensing circuit, according to an embodiment of the disclosure;

FIG. 14B is a diagram for detecting a position of an overheating occurrence in an SMPS configuration, according to an embodiment of the disclosure;

FIG. 14C is a diagram for detecting a position of an overheating occurrence in an SMPS configuration, according to an embodiment of the disclosure;

FIG. 15 is a flowchart for performing overheating prevention for a cordless cleaner by using a temperature sensing circuit provided in an SMPS, according to an embodiment of the disclosure;

FIG. 16 is a waveform diagram illustrating an overheating protection operation according to an embodiment of the disclosure;

FIG. 17 is a diagram illustrating a robot cleaner as a cordless cleaner that includes a temperature sensing circuit for overheating prevention, according to an embodiment of the disclosure;

FIG. 18 is a diagram illustrating an air conditioner as a home appliance that includes a temperature sensing circuit for overheating prevention, according to an embodiment of the disclosure;

FIG. 19 is a diagram illustrating a refrigerator as a home appliance that includes a temperature sensing circuit for overheating prevention, according to an embodiment of the disclosure;

FIG. 20 is a diagram illustrating a washing machine as a home appliance that includes a temperature sensing circuit for overheating prevention, according to an embodiment of the disclosure;

FIG. 21 is a diagram illustrating an electric oven as a home appliance that includes a temperature sensing circuit for overheating prevention, according to an embodiment of the disclosure; and

FIG. 22 is a diagram illustrating an induction cooking apparatus as a home appliance that includes a temperature sensing circuit for overheating prevention, according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

As used herein, the expression “at least one of a, b, or c” may indicate only a, only b, only c, both a and b, both a and c, both b and c, all of a, b, and c, or variations thereof.

Throughout the disclosure, when a part “includes” an element, it is to be understood that the part may additionally include other elements rather than excluding other elements as long as there is no particular opposing recitation. In addition, as used herein, the terms such as “ . . . er (or)”, “ . . . unit”, “ . . . module”, etc., denote a unit that performs at least one function or operation, which may be implemented as hardware or software or a combination thereof.

Hereinafter, embodiments of the disclosure will be described in detail with reference to the accompanying drawings to allow those of skill in the art to easily carry out the embodiments. An embodiment of the disclosure may, however, be embodied in many different forms and should not be construed as being limited to the embodiment set forth herein. In addition, parts in the drawings unrelated to the detailed description are omitted to ensure clarity of an embodiment of the disclosure, and like reference numerals in the drawings denote like elements.

There is a need for a method of protecting, when overheating occurs, a home appliance from the overheating, and for a home appliance employing the method, according to an embodiment of the disclosure. Furthermore, there is a need for a method of preventing overheating, which allows a designer to freely set an overheating prevention level by using an existing power conversion device (a switched-mode power supply (SMPS), without adding a separate microcomputer. Hereinafter, a home appliance employing a method of preventing overheating will be described, focusing on a cleaner device as an example of the home appliance, but the home appliance according to the disclosure is not limited thereto, and the description may be applied to any home appliance equipped with a power conversion device including a pulse-width modulation (PWM) controller. Examples of home appliances equipped with a power conversion device including a PWM controller may include, but are not limited to, a refrigerator, a dryer, a television (TV), a washing machine, an air conditioner, a dishwasher, an induction cooker, and a radiant electric cooktop.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

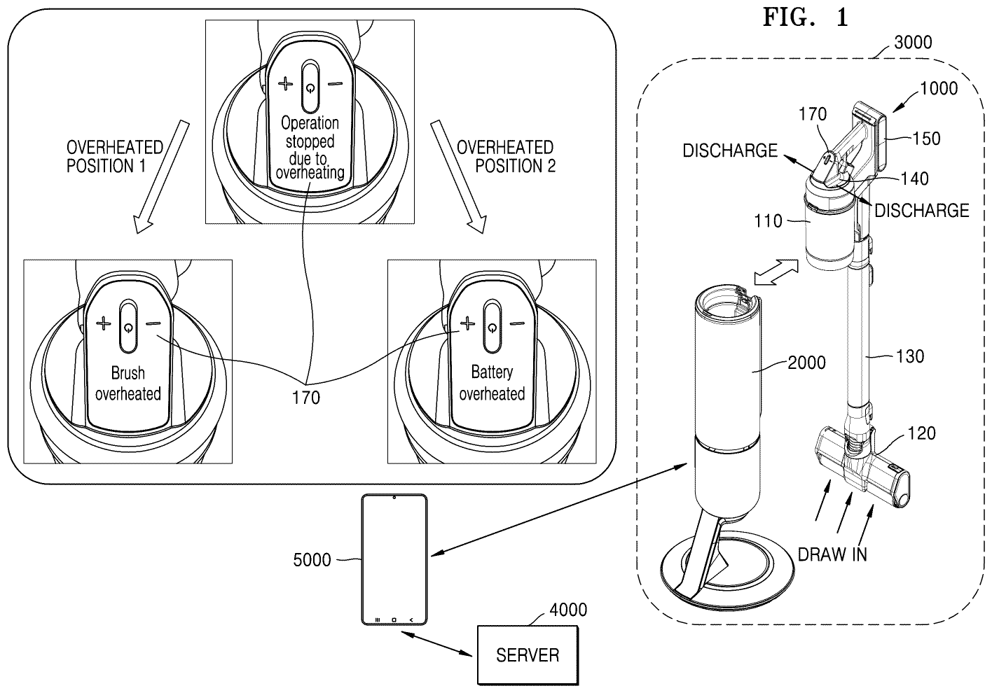

FIG. 1 a diagram illustrating a cordless cleaner device, which is a type of home appliance including a combination of a station and a cleaner main body, according to an embodiment of the disclosure.

Referring to FIG. 1, according to an embodiment of the disclosure, a cordless cleaner 3000 with a combination of a station 2000 and a cleaner main body 1000 may be a stick-type cleaner where the cleaner main body 1000 includes a brush device 120, an extension pipe 130, and a battery 150. The cordless cleaner 3000 according to an embodiment of the disclosure may be a handheld-type cleaner including the cleaner main body 1000 and the brush device 120. The cordless cleaner 3000 according to an embodiment of the disclosure may be a cordless cleaner including the cleaner main body 1000, the brush device 120, the extension pipe 130, and the station 2000. The cordless cleaner 3000 according to an embodiment of the disclosure may be a cleaner selectively usable as a handheld-type, an automatic moving-type, or a stick-type cleaner. A handheld-type cleaner, an automatic moving-type cleaner, and/or a stick-type cleaner according to an embodiment of the disclosure may be a cordless cleaner.

The cleaner main body 1000 according to an embodiment of the disclosure is a part that a user may hold and move during cleaning. The cleaner main body 1000 may include a dust container (or dust collecting container) 110 to receive foreign substances drawn in from a surface to be cleaned (e.g., a floor (e.g., a hard floor, a carpet, or a mat), bedding, or a sofa). The cleaner main body 1000 may include a filter unit 140 to filter out ultrafine dust and the like that have not filtered out by the dust container 110, and to discharge air from which the ultrafine dust has been removed, to the outside of the cleaner main body 1000. The cleaner main body 1000 may include a pressure sensor (not shown) used to detect a pressure value within a dust suction flow path (hereinafter, referred to as dust suction flow path pressure). The dust suction flow path of the cleaner main body 1000 may be a flow path extending from a location where the suction of air containing foreign substances begins, to a location where air, from which foreign substances have been removed, is discharged. For example, the dust suction flow path of the cleaner main body 1000 may refer to a section from a suction port of the brush device 120 to the filter unit 140 of the cleaner main body 1000, but is not limited thereto. The cleaner main body 1000 may include a battery 150 to supply power to the cleaner main body 1000. The cleaner main body 1000 may include a user interface 170 for receiving a user input and outputting information about a self-diagnosis result of the cordless cleaner 3000.

As illustrated in FIG. 1, various pieces of information may be displayed on the user interface 170. For example, when a processor of the cleaner main body 1000 detects overheating and determines that further cleaner operation is unsafe, it may stop the cleaner operation and display a message such as “Operation stopped due to overheating” on the user interface 170, and furthermore, when the overheated position may be indicated, detailed information about the overheated position, such as “Brush overheated” or “Battery overheated”, may also be displayed following the “Operation stopped due to overheating” message. Through the user interface 170, the cordless cleaner 3000 may inform the user about the reason for the overheating and indicate in detail the overheated position in the cordless cleaner 3000.

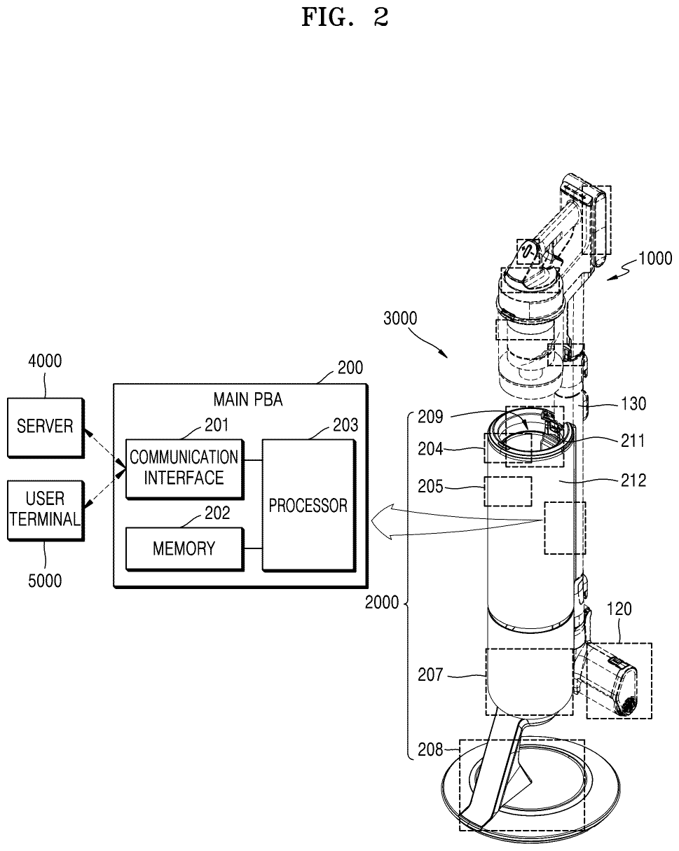

FIG. 2 is a diagram for describing a station and a cleaner main body, according to an embodiment of the disclosure.

Referring to FIG. 2, a main printed board assembly (PBA) 200 of the station 2000 according to an embodiment of the disclosure may include a communication interface 201, memory 202, and at least one processor 203. The at least one processor 203 may be referred to as a ‘station processor’. In FIG. 2, a cable connector 205, a second suction motor 207, an SMPS 208, and a collection unit 212 are arranged inside the station 2000, and thus indicated by dashed quadrangles representing their location.

The station 2000 may include a user interface 204, the cable connector 205 (e.g., Home Appliance Smart Service (HASS)), the second suction motor 207, the SMPS 208 serving as a power conversion device, a flow path 209 connected to the dust container of the cleaner main body 1000, a charging terminal 211 for charging the battery 150 of the cleaner main body 1000, a dust container coupling unit, the collection unit 212, a filter unit, and the like. The second suction motor 207 is referred to as such in order to distinguish it from a first suction motor (not shown) of the cleaner main body 1000. Hereinafter, each component will be described.

The station 2000 may include the communication interface 201 configured to perform communication with an external device. For example, the station 2000 may perform communication with the cleaner main body 1000 of the cordless cleaner 3000, a user terminal 5000, or a server 4000 via the communication interface 201. Here, the communication interface 201 may communicate with the server 4000 via a first communication method (e.g., a Wi-Fi communication method) and communicate with the cleaner main body 1000 via a second communication method (e.g., a Bluetooth Low Energy (BLE) communication method).

The communication interface 201 may include a short-range wireless communication interface, a long-range wireless communication interface, and the like. The short-range wireless communication interface may include, but is not limited to, a Bluetooth communication unit, a BLE communication unit, a near-field communication (NFC) unit, a wireless local area network (WLAN) (Wi-Fi) communication unit, a Zigbee communication unit, an Infrared Data Association (IrDA) communication unit, a Wi-Fi Direct (WFD) communication unit, an ultra-wideband (UWB) (UWB) communication unit, an Ant+ communication unit, and the like. The long-range wireless communication interface may be used by the station 2000 to communicate remotely with the server 4000. The long-range wireless communication interface may include the Internet, a computer network (e.g., a local area network (LAN) or a wide area network (WAN)), and a mobile communication unit. The mobile communication unit may include, but is not limited to, a 3^{rd} Generation (3G) module, a 4^{th} Generation (4G) module, a 5^{th} Generation (5G) module, a Long-Term Evolution (LTE) module, a Narrowband Internet of Things (NB-IoT) module, an LTE for Machines (LTE-M) module, and the like.

The communication interface 201 may transmit data to the at least one processor 203 via Universal Asynchronous Receiver/Transmitter (UART), which is asynchronous communication, but the communication method is not limited thereto.

The memory 202 of the station 2000 may store a program (e.g., one or more instructions) enabling the at least one processor 203 to control the overall operation of the cordless cleaner 3000 or the station 2000, and may also store input/output data. For example, the memory 202 of the station 2000 may store, but is not limited to, software associated with controlling the station 2000, overheating state data, overheating history data, overheating position information data, error occurrence data (failure history data), types of operation events, information associated with charging of the battery 150 (e.g., a charging interval, data regarding a time point of recent compensation charge, or the charge level of the battery 150 during recent compensation charge), and the like. The memory 202 of the station 2000 may also store data received from the cleaner main body 1000. For example, the memory 202 may store product information (e.g., identification information or model information) about the cordless cleaner 3000 docked in the station 2000, version information about software installed on the cordless cleaner 3000, error occurrence data (failure history data) regarding the cordless cleaner 3000, temperature data regarding the station 2000 or the cleaner main body 1000, information associated with charging of the battery 150, and the like.

The memory 202 may include at least one of flash memory-type storage medium, a hard disk-type storage medium, a multimedia card micro-type storage medium, card-type memory (e.g., Secure Digital (SD) or extreme Digital (XD) memory), random-access memory (RAM), static RAM (SRAM), read-only memory (ROM), electrically erasable programmable ROM (EEPROM), programmable ROM (PROM), magnetic memory, a magnetic disk, and an optical disc. Programs stored in the memory 202 may be classified into a plurality of modules according to their functions.

The station 2000 may include the main PBA 200, and the main PBA 200 may include the at least one processor 203. The station 2000 may include one processor or may include a plurality of processors. The at least one processor 203 according to the disclosure may include at least one of a central processing unit (CPU), a graphics processing unit (GPU), an accelerated processing unit (APU), a many-integrated core (MIC) processor, a digital signal processor (DSP), and a neural processing unit (NPU). The at least one processor 203 may be implemented in the form of an integrated system on a chip (SoC) including one or more electronic components. The at least one processor 203 may each be implemented as separate hardware (H/W). The at least one processor 203 may also be referred to as a microprocessor controller (MICOM), a microprocessor unit (MPU), or a microcontroller unit (MCU).

The at least one processor 203 according to the disclosure may be implemented as a single-core processor or a multi-core processor.

In an embodiment, when overheating occurs in the cordless cleaner 3000, the at least one processor 203 may detect the overheated position and control a display of the cleaner main body 1000 to display the overheated position.

The user interface 204 of the station 2000 may include an input interface and an output interface. The input interface may include a dust discharge button, a mode selection button, and the like, which allow a user input. The output interface may include, but is not limited to, a light-emitting diode (LED), a liquid-crystal display (LCD), a touch screen, and the like. The output interface may display, but is not limited to, the amount of charge of the battery 150 of the cleaner main body 1000, software update progress information, operation event information, and the like.

The station 2000 may include the cable connector 205. The cable connector 205 may include a terminal for connecting to a computing device of a system administrator (e.g., a service technician).

The second suction motor 207 of the station 2000 may be a device configured to generate suction force for discharging, from the cleaner main body 1000, foreign substances collected in the dust container 110 of the cleaner main body 1000. The second suction motor 207 may rotate a suction fan that moves air. The suction fan may include an impeller.

The SMPS 208 is a power conversion device configured to receive alternating current input power 10 from a power source and convert it into direct current power. When the cleaner main body 1000 is coupled to the station 2000, direct current power generated by the SMPS 208 may be supplied to the battery 150 of the cleaner main body 1000 via the charging terminal 211, allowing the battery 150 to be charged. Throughout the specification, the term ‘power conversion device’ may be used interchangeably with the term ‘SMPS’.

The charging terminal 211 connects to a charging terminal 151 of the cleaner main body 1000 and is then used to charge the battery 150 included in the cleaner main body 1000. The charging terminal 211 may be connected to the SMPS 208, to provide an electrical connection for charging the battery 150 by directing, to the battery 150, a direct current voltage (e.g., 30 V) output from the SMPS 208.

The dust container coupling unit may be arranged such that the dust container 110 of the cleaner main body 1000 is coupled to the station 2000. Coupling between the cleaner main body 1000 and the station 2000 may be completed when the dust container 110 is seated in the dust container coupling unit. The dust container coupling unit may include a docking detection sensor configured to detect coupling or docking of the cleaner main body 1000. The docking detection sensor may be, but is not limited to, a tunnel magneto-resistance (TMR) sensor. The TMR sensor may sense whether the cleaner main body 1000 is docked, by detecting a magnetic body attached to a dust container. The station 2000 may include a step motor configured to press one side of a dust container door to open it when the dust container 110 is docked to the station 2000.

The collection unit is a space in which foreign substances discharged from the dust container of the cleaner main body 1000 may be collected. The collection unit may include a dust bag in which foreign substances discharged from the dust container are collected. The dust bag may be formed of a material permeable to air but impermeable to foreign substances, such that foreign substances flowing into the collection unit from the dust container are collected in the dust bag. The dust bag may be arranged to be detachable from the collection unit. The station 2000 may also include an ultraviolet emission unit configured to emit ultraviolet rays toward the collection unit. The ultraviolet emission unit may include a plurality of ultraviolet lamps.

The cordless cleaner 3000 according to an embodiment of the disclosure may be a stick-type cleaner including the cleaner main body 1000, the brush device 120, and the extension pipe 130. However, the cordless cleaner 3000 according to an embodiment of the disclosure is not limited to a stick-type cleaner, and the cleaner main body 1000 may be an automatic moving-type cleaner, such as a robot cleaner.

Not all the components illustrated in FIG. 2 are essential components. The cordless cleaner 3000 may be implemented with more or fewer components than those illustrated in FIG. 2. For example, the cordless cleaner 3000 may be implemented with the cleaner main body 1000 and the brush device 120, excluding the extension pipe 130.

The cleaner main body 1000 is a part that a user may hold and move during cleaning, and the cleaner main body 1000 may include a first suction motor 111 configured to form a vacuum inside the cordless cleaner 3000. The first suction motor 111 may be positioned inside the dust container 110 in which foreign substances drawn in from a surface to be cleaned (e.g., a floor, bedding, or a sofa) are accommodated. The cleaner main body 1000 may further include, in addition to the first suction motor 111, at least one main processor (not shown), the battery 150, memory (not shown) storing software associated with controlling the cordless cleaner 3000, and the like, but is not limited thereto. The cleaner main body 1000 is not limited to a part that a user may hold and move, and may be a main body of an automatically moving-type cleaner, such as a robot cleaner, that moves automatically. In this case, a space detection sensor configured to detect a space and wheels for automatic movement may be attached to the cleaner main body 1000.

The brush device 120 is a device to be brought into close contact with a surface to be cleaned and draw in air and foreign substances from the surface to be cleaned. The brush device 120 may also be referred to as a cleaner head. The brush device 120 may be rotatably coupled to the extension pipe 130. The brush device 120 may include, but is not limited to, a motor, a drum having a rotating brush attached thereto, and the like. According to an embodiment of the disclosure, the brush device 120 may further include a processor for the brush device 120, which is configured to control communication with the cleaner main body 1000. Various types of brushes may be used for the brush device 120.

The extension pipe 130 may be formed as a pipe or as a flexible hose with a certain rigidity. The extension pipe 130 may transmit, to the brush device 120, suction force generated by the suction motor of the cleaner main body 1000, and may move, to the cleaner main body 1000, air and foreign substances drawn in via the brush device 120. The extension pipe 130 may be detachably connected to the brush device 120. The extension pipe 130 may be formed in a plurality of stages between the cleaner main body 1000 and the brush device 120. Two or more extension pipes 130 may be provided.

According to an embodiment of the disclosure, each of the cleaner main body 1000, the brush device 120, and the extension pipe 130 included in the cordless cleaner 3000 may include power lines (e.g., a positive (+) power line and a negative (−) power line) and signal lines.

The power lines may be lines for transmitting power supplied from the battery 150, to the cleaner main body 1000 and to the brush device 120 connected to the cleaner main body 1000. The signal lines, which are different from the power lines, may be lines for transmitting and receiving signals between the cleaner main body 1000 and the brush device 120. The signal lines may be implemented to be connected to the power lines within the brush device 120.

According to an embodiment of the disclosure, each of the at least one main processor of the cleaner main body 1000 and the processor of the brush device 120 may perform bidirectional communication between the cleaner main body 1000 and the brush device 120 by controlling an operation of a switch element connected to the signal lines. Hereinafter, communication between the cleaner main body 1000 and the brush device 120, when performed via the signal lines, may be defined as ‘signal line communication’. In addition, the cleaner main body 1000 and the brush device 120 may also communicate with each other by using Inter-Integrated Circuit (I2C) or UART.

According to an embodiment of the disclosure, the cleaner main body 1000 may detect whether the brush device 120 is attached or detached, and identify the type of the brush device 120, and may adaptively control an operation of the brush device 120 (e.g., the revolutions per minute (RPM) of the drum) according to a usage environment state of the brush device 120 (e.g., a hard floor, a carpet, a mat, a corner, or whether it is lifted from the surface to be cleaned). For example, the main processor (not shown) of the cleaner main body 1000 may periodically communicate with the processor (not shown) of the brush device 120, to transmit, to the brush device 120, a signal for controlling an operation of the brush device 120.

The cleaner main body 1000 of the cordless cleaner 3000 may have a rechargeable battery 150 embedded therein. The battery 150 may enable cordless vacuum cleaning, eliminating the need to connect a power cord to an outlet during cleaning. Thus, the cordless cleaner 3000 according to the disclosure may refer to a cordless vacuum cleaner, but is not limited thereto. The cordless cleaner 3000 may include a robot cleaner, wherein the cleaner main body 1000 automatically moves over a surface to be cleaned while automatically performing cleaning. By using a handle mounted on the cleaner main body 1000 the user may move the cleaner main body 1000 back and forth such that the brush device 120 draws in dust or foreign substances (debris) from a surface to be cleaned. The cleaner main body 1000 may include a communication interface configured to perform communication with the station 2000.

The station 2000 may be a device for discharging dust collected in the cleaner main body 1000, charging the battery of the cleaner main body 1000, or docking the cleaner main body 1000. The station 2000 may also be referred to as a cleaning station. According to an embodiment of the disclosure, the station 2000 may perform communication with the cleaner main body 1000 or the server 4000 via a network. For example, the station 2000 may transmit and receive data to and from the cleaner main body 1000 via a wireless personal area network (WPAN) without using an access point (AP). The station 2000 may transmit and receive data to and from the server 4000 via an AP that connects a LAN, to which the station 2000 is connected, to a WAN, to which the server 4000 is connected. For example, the station 2000 may be connected to the cleaner main body 1000 via BLE communication, and may be connected to the server 4000 via Wi-Fi (Institute of Electrical and Electronics Engineers (IEEE) 802.11) communication.

Thus, in a case in which a Wi-Fi communication module is not provided in the cleaner main body 1000, the station 2000 may serve to relay communication between the cleaner main body 1000 and the server 4000. For example, the station 2000 may upload, to the server 4000, data received from the cleaner main body 1000. In addition, the station 2000 may also transmit, to the cleaner main body 1000, data received from the server 4000.

The server 4000 illustrated in FIG. 1 may be a device for managing the station 2000 and the cleaner main body 1000. For example, the server 4000 may be a home appliance management server. The server 4000 may manage user account information and information about home appliances connected to user accounts. For example, a user may access the server 4000 via the user terminal 5000 illustrated in FIG. 1 and then create a user account. The user account may be identified by an identifier (ID) and a password both set by the user. The server 4000 may register the station 2000 and the cleaner main body 1000 with a user account according to a predetermined procedure. For example, the server 4000 may register the station 2000 and the cleaner main body 1000 by linking identification information of the station 2000 (e.g., a serial number or a medium access control (MAC) address) and identification information of the cleaner main body 1000 to the user account. When the station 2000 and the cleaner main body 1000 are registered in the server 4000, the server 4000 may manage the state of the station 2000 or the state of the cleaner main body 1000 by periodically receiving, from the station 2000, state information about the station 2000 or state information about the cleaner main body 1000.

In addition, when software associated with controlling the station 2000 or software associated with controlling the cleaner main body 1000 is updated (hereinafter, also referred to as ‘upgraded’), a new version of the software may be registered in the memory of the server 4000. When a download request for a new version of software is received from the station 2000, the server 4000 may transmit the new version of software to the station 2000. Here, the software may also be referred to as firmware.

When the new version of software is software associated with controlling the station 2000, the station 2000 may download the new version of software to update software previously installed on the station 2000. According to an embodiment of the disclosure, the software associated with controlling the station 2000 may include, but is not limited to, an algorithm associated with a dust discharge operation (stroke) (e.g., an algorithm for adjusting the intensity of suction force of the second suction motor of the station 2000), an algorithm associated with an operation of an output interface (e.g., an LCD or an audio output unit), an algorithm for diagnosing a state of the station 2000, and the like.

Furthermore, when the new version of software is software associated with controlling the cleaner main body 1000, the station 2000 may transmit the new version of software to the cordless cleaner 3000 to update software previously installed on the cordless cleaner 3000. According to an embodiment of the disclosure, the software associated with controlling the cleaner main body 1000 may include, but is not limited to, an artificial intelligence (AI) model trained to infer a usage environment state of the brush device 120, a control algorithm associated with an operation mode of the cleaner main body 1000 (e.g., an algorithm for controlling the intensity of suction force of a suction motor of the cleaner main body, an algorithm for controlling the RPM of the rotating brush of the brush device 120 (hereinafter referred to as drum RPM)), an algorithm for diagnosing a state of the cleaner main body 1000 (e.g., filter clogging, dust suction flow path clogging, overload of the brush device 120, or incorrect assembly), and the like.

Thus, according to an embodiment of the disclosure, even in a case in which the cleaner main body 1000 does not include a separate communication module (e.g., a Wi-Fi communication module) capable of direct communication with the server 4000, the cleaner main body 1000 may conveniently update previously installed software in an over-the-air (OTA) manner by downloading, via the station 2000 connected to the server 4000, a new version of software registered in the server 4000. OTA refers to a technology for wirelessly updating software (firmware) by using Wi-Fi communication or the like, without connecting to a computer. OTA may also be referred to as ‘over-the-network (OTN)’.

In addition, according to an embodiment of the disclosure, even without purchasing a new cordless cleaner 3000, the user may update a control algorithm or learning model of the existing cordless cleaner 3000 to the latest version, and thus, the user convenience of the cordless cleaner 3000 may be improved.

The station 2000 may download, to the cordless cleaner 3000, a new version of software associated with controlling the cordless cleaner 3000, such that the software of the cordless cleaner 3000 is updated.

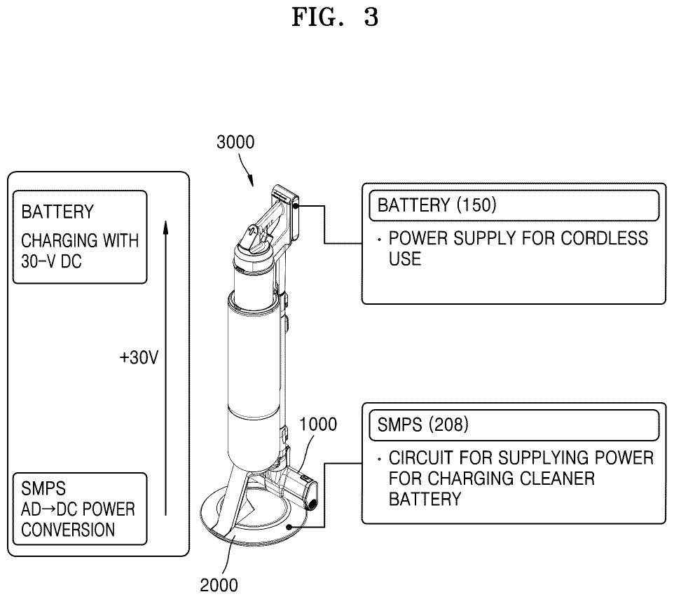

FIG. 3 is a configuration diagram of a cordless cleaner using a battery, according to an embodiment of the disclosure.

Referring to FIG. 3, the cleaner main body 1000 may be docked in the station 2000 of the cordless cleaner 3000, the station 2000 may be directly connected to an input alternating current power source, and the SMPS 208 of the station 2000 may generate a direct current voltage for charging the battery 150 included in the cleaner main body 1000.

The battery 150 serves to supply power such that the cleaner main body 1000, when detached from the station 2000, may be used without a power cord. For example, the battery 150 may be charged with a direct current voltage of 30 V via the SMPS 208, but is not limited thereto, and the magnitude of the charging voltage (or driving direct current voltage) may vary according to the specifications of the battery 150. The SMPS 208 may receive, as input, alternating current (AC) power supplied to the station 2000 and convert the AC voltage to a direct current (DC) voltage. The SMPS 208 may include a switching element for AC-DC conversion, and a PWM controller for driving the switching element. The switching element included in the SMPS 208 may be, but is not limited to, any one of a field-effect transistor (FET), a metal-oxide-semiconductor field-effect transistor (MOSFET), an insulated-gate bipolar transistor (IGBT), or a transistor (TR). As illustrated in FIG. 3, the SMPS 208 may be positioned on a bottom surface of the station 2000 to which input AC power may be supplied, but is not limited thereto, and may be positioned on any surface of the station 2000.

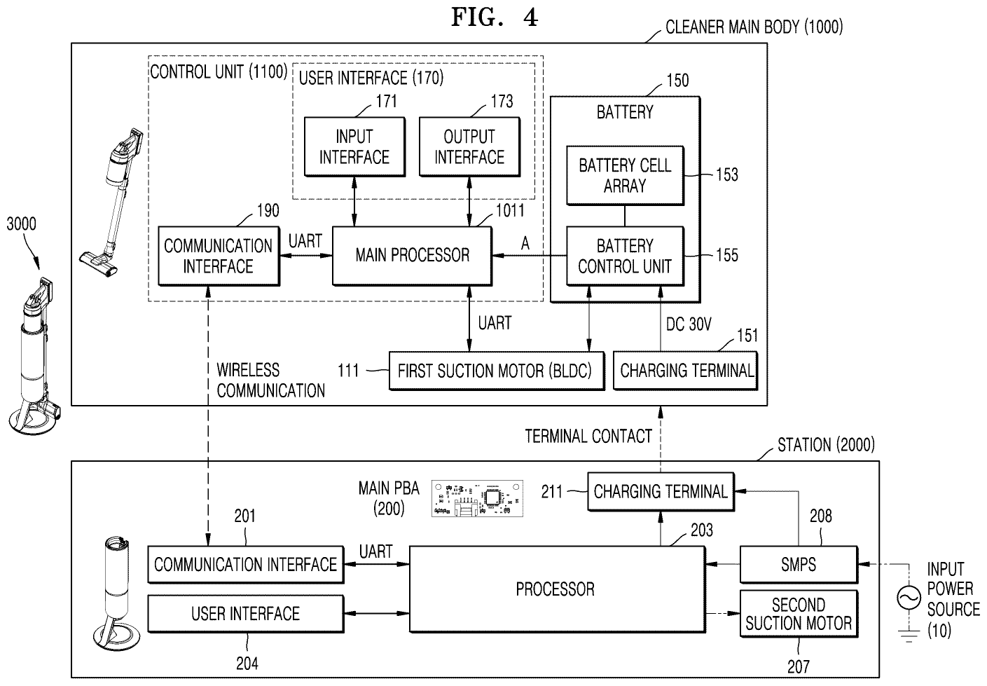

FIG. 4 is a block diagram of a cordless cleaner according to an embodiment of the disclosure.

Referring to FIG. 4, the cleaner main body 1000 and the station 2000 may be electrically connected to each other via their charging terminals 151 and 211. First, examining the cleaner main body 1000, the cleaner main body 1000 may include a control unit 1100, the battery 150, the first suction motor 111, and the charging terminal 151. The first suction motor 111 is used to draw in debris or dust via the cleaner main body 1000 during a cleaning operation, and the charging terminal 151 is a terminal that enables an electrical connection with the station 2000 for charging the battery 150 with direct current voltage generated by the SMPS 208 of the station 2000.

The control unit 1100 may include the user interface 170, a communication interface 190, and (at least one) main processor 1011. The battery 150, which may also be referred to as a battery pack, may include a battery cell array 153 in which electricity is charged, and a battery control unit 155 configured to control the battery 150.

The user interface 170 may include an input interface 171, via which commands may be input to the cordless cleaner 3000, and an output interface 173, via which the cordless cleaner 3000 displays information to the user. The input interface 171 may include a user input interface capable of touch recognition. The output interface 173 may include, but is not limited to, an LCD or a light-emitting diode (LED) display. The output interface 173 may display various pieces of information, including state information about the cordless cleaner 3000, to the user. For example, when the cordless cleaner 3000 overheats, the output interface 173 may indicate whether overheating has occurred and, according to an embodiment, may also display position information about which part within the cordless cleaner 3000 is overheating. In addition, the output interface 173 may provide information such as an operation state of the cordless cleaner 3000, a display of an amount of charge, or whether the battery is charged.

The main PBA 200 of the station 2000 may include the processor 203, the communication interface 201, and the user interface 204. The main PBA 200, depending on the design, may be configured as a printed circuit board (PCB) separate from the SMPS 208, or may be manufactured as an integral PCB with the SMPS 208.

The station 2000 may primarily perform automatic/manual dust emptying and communication with the cleaner main body 1000 via a communication connection (e.g., Wi-Fi or BLE). The SMPS 208 of the station 2000 receives AC voltage from the input power source 10. The SMPS 208 may generate a desired DC voltage via PWM switching of a switch such as a FET, under control of an internal PWM controller (a PWM controller-integrated circuit). For example, to charge the battery 150 of the cleaner main body 1000, the SMPS 208 may generate a DC voltage of 30 V. In addition, as needed, the SMPS 208 may also generate a DC voltage of 5 V or 3.3 V such that the processor 203 of the station 2000 may operate.

As illustrated in FIG. 4, the cordless cleaner 3000 using the battery 150 may experience overheating during operations that use power, such as a cleaning operation, a battery charging operation, or other dust discharge operations. Overheating may frequently occur around the SMPS 208. In this case, because the PWM controller included in the SMPS 208 has its own overheating protection function, the cordless cleaner 3000 may be protected from overheating by using this function. However, the overheating protection function inherently included in the PWM controller is configured such that an overheating protection operation is performed only according to temperature specifications defined by the manufacturer of the PWM controller. Furthermore, because the temperature sensing position is also dependent on the position of the PWM controller, when the overheating protection function of the PWM controller is used as is, the degree of freedom for the temperature sensing position is not high. Thus, there is a need for a method of preventing overheating, or a temperature sensing circuit, that allows for freely setting an overheating temperature while providing a high degree of freedom for a temperature sensing position, such that temperature sensing may be performed at positions where overheating of the cordless cleaner 3000 frequently occurs, and a cordless cleaner employing the method or temperature sensing circuit. Furthermore, costs may also be reduced when an overheating protection function of an existing PWM controller is used as is for using the method of preventing overheating, without using an additional MICOM.

Table 1 below shows, as an example, specifications associated with the overheating protection function of the PWM controller used in the SMPS 208 when overheating occurs in the cordless cleaner 3000, according to an embodiment of the disclosure.

TABLE 1

| Parameter | Symbol | Min. | Typ. | Max. | Units |
|---|---|---|---|---|---|
| Thermal Shutdown Operating | T_{j(TSD)} | 127 | 145 | — | ° C. |
| Temperature | | | | | |

According to Table 1 above, the temperature for overheating protection is a minimum of 127 degrees Celsius and typically 145 degrees Celsius. These are specifications determined by the manufacturer of the PWM controller, and thus, the manufacturer of the cordless cleaner 3000 cannot freely select a threshold temperature for overheating protection. Furthermore, for the PWM controller to operate to protect from overheating, the PWM controller detects overheating only when the ambient temperature around the PWM controller increases, and thus, the degree of freedom for the temperature sensing position is not high. Therefore, when a position where the temperature has increased and thus overheating has occurred is spaced apart from the position of the PWM controller, the SMPS 208 may not stop its operation despite the occurrence of overheating, and power may continue to be supplied to the cordless cleaner 3000, potentially leading to a fire.

When the SMPS 208 overheats, the PCB including the SMPS 208 may burn out, causing damage not only to the components constituting the SMPS 208 but also to parts of the cordless cleaner 3000 adjacent to the SMPS 208.

Thus, there is a need for a method of preventing overheating or a method for temperature sensing, that provides a high degree of freedom for an overheating detection position and allows a user to freely set an overheating detection temperature, according to the disclosure. The method of preventing overheating may prevent, in advance, fire, malfunction, and damage due to overheating of a cordless cleaner, and enable a user to use the cordless cleaner more safely. Furthermore, a cleaner device according to the disclosure may use an overheating protection function of an existing PWM controller as is, without using a separate MICOM, while additionally allowing a temperature sensing circuit to be arranged at a desired overheating detection position. Because a separate microcomputer or an analog-to-digital (A/D) converter is not used for the temperature sensing circuit, cost increase may be minimized. In addition, the disclosure allows an overheating protection area to be expanded by increasing the degree of freedom for the position of a temperature sensing circuit, in addition to preventing overheating of the SMPS 208 via the temperature sensing circuit. Furthermore, the disclosure enables a simple configuration of a temperature sensing circuit with minimal circuitry by utilizing an input voltage detection circuit employed in existing SMPSs.

The user interface 204 of the station 2000 may display various pieces of information for showing the state of the cordless cleaner 3000 to the user. For example, when the cordless cleaner 3000 overheats, the user interface 204 may indicate, via the display, whether overheating has occurred, and according to an embodiment, may also display position information about which part within the cordless cleaner 3000 is overheating. In addition, the user interface 204 may also provide information such as an operation state of the cordless cleaner 3000, a display of a charge amount, or whether the battery is charged.

As described above, a home appliance employing the method of preventing overheating according to the disclosure is not limited to a cordless cleaner. Thus, a home appliance employing the method of preventing overheating according to the disclosure may differ from the components of the cordless cleaner illustrated in FIG. 4. However, a home appliance employing the method of preventing overheating according to the disclosure may essentially include at least the SMPS 208 illustrated in FIG. 4.

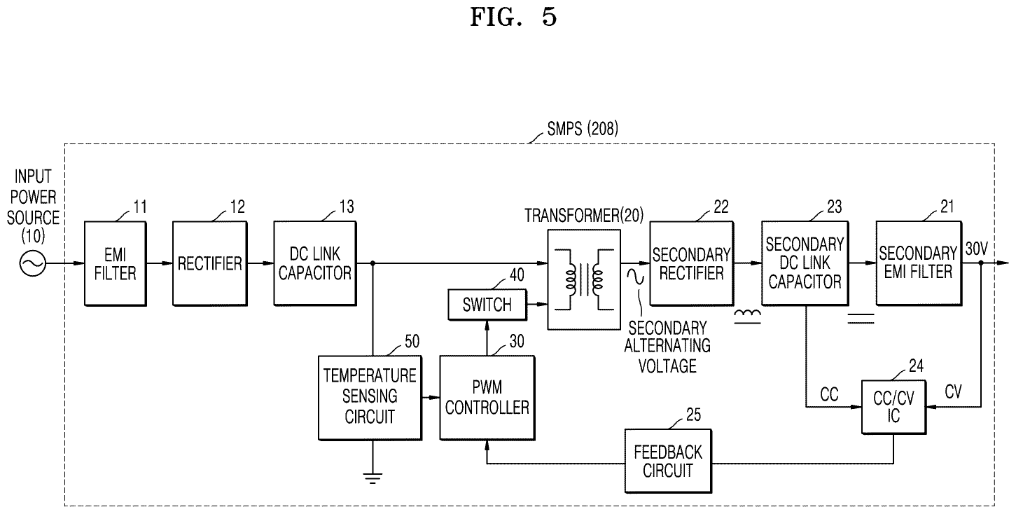

FIG. 5 is a block diagram of an SMPS according to an embodiment of the disclosure.

Referring to FIG. 5, the SMPS 208 receives input power 10, which is an AC voltage. Although the magnitude of the AC voltage may vary depending on specifications, it may be within a range of 90 V to 230 V. However, because some countries use lower or higher AC voltage magnitudes, the above numerical values are only approximate and are not intended to limit the range of the AC voltage magnitude.

The SMPS 208 is a power conversion device configured to convert an AC voltage received via the input power source 10, into a required DC voltage (e.g., DC 5 V and/or DC 30 V). Thus, throughout the specification, the SMPS 208 may be referred to interchangeably as a power conversion device or a power conversion unit.

The AC voltage from the input power source 10 has noise removed via an electromagnetic interference (EMI) filter 11 and then converted into a DC voltage via a rectifier 12. The rectifier 12 mainly includes diodes, but is not limited thereto, and may include switching elements such as thyristors or IGBTs. The DC voltage produced via the conversion via the rectifier 12 is smoothed via a DC link capacitor 13. The DC voltage across the DC link capacitor 13 may be converted again into an AC voltage of a desired magnitude and a desired frequency by PWM switching of a switch 40 device, under control of a PWM controller 30. The converted AC voltage passes through a transformer 20 for insulation, filtering, and/or changing the voltage magnitude. The secondary-side output of the transformer 20 is a secondary AC voltage, and the secondary AC voltage is rectified again into a secondary DC voltage via a secondary rectifier 22. The secondary DC voltage is smoothed via a secondary DC link capacitor 23. The smoothed secondary DC voltage passes through a secondary EMI filter 21 for denoising, and the DC voltage (e.g., DC 30 V) that has passed through the secondary EMI filter 21 may be used to charge the battery 150 of the cleaner main body 1000 via a charging terminal.

In FIG. 5, a constant current (CC)/constant voltage (CV) integrated circuit (IC) 24 is a circuit or IC configured to control conversion to a CC mode or a CV mode during battery charging. When the amount of discharge of the battery 150 is large, its voltage may drop below a full-charge voltage (e.g., 30 V). Thus, when charging the battery 150, charging proceeds in the CC mode under control of the CC/CV IC 24 up to a certain percentage point relative to a full charge (e.g., 80% relative to the full charge), and thereafter, the battery 150 is charged in the CV mode.

A feedback circuit 25, while monitoring an output stage (e.g., 30 V) for charging the battery 150, provides feedback to the PWM controller 30 such that the charging output to the battery 150 remains constant. For example, when the charging output to the battery 150 reaches 32 V, the feedback circuit 25 provides overvoltage feedback to the PWM controller 30. The PWM controller 30 that has received the overvoltage feedback controls the switching of the switch 40 to decrease, such that the output voltage of the SMPS 208 decreases. On the contrary, when the charging output to the battery 150 is 27 V, the feedback circuit 25 provides low-voltage feedback to the PWM controller 30. The PWM controller 30 that has received the low-voltage feedback controls the switching of the switch 40 to increase, such that the output voltage of the SMPS 208 increases.

The PWM controller 30 is responsible for a function of controlling the output of the SMPS 208, and may typically have the form of an IC that is pre-manufactured by a chip manufacturer. The PWM controller 30 may control the switch 40 such that PWM switching is performed. In an embodiment, when a temperature sensor 52 included in a temperature sensing circuit 50 senses a temperature in a vicinity of the temperature sensor 52, and accordingly, provides a voltage input to an overheating protection input of the PWM controller 30, the PWM controller 30, in response to determining that overheating has occurred, may perform an overheating prevention operation such as discontinuing the switching of the switch 40. The overheating protection input of the PWM controller 30 is an input pin for performing, when overheating has occurred in the cordless cleaner 3000, an overheating protection function that is provided in the PWM controller 30 used in the SMPS 208. Specifications regarding the input pin for performing the overheating protection function have been described with reference to Table 1 above. Throughout the specification, the input pin in the PWM controller 30 for performing the overheating protection function may be simply referred to as a ‘BR’ pin.

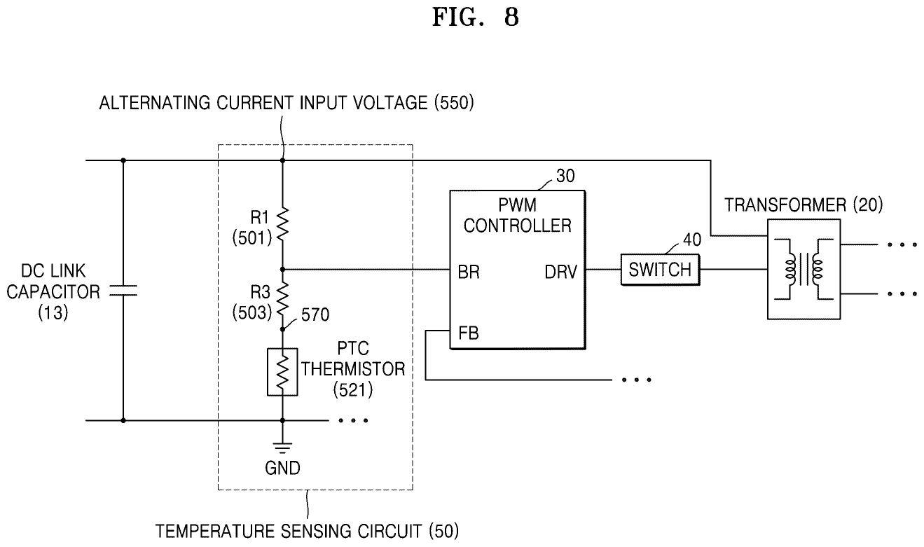

Embodiments in which the arrangement and type of the temperature sensor 52 in the temperature sensing circuit 50 vary will be described with reference to FIGS. 8 to 13.

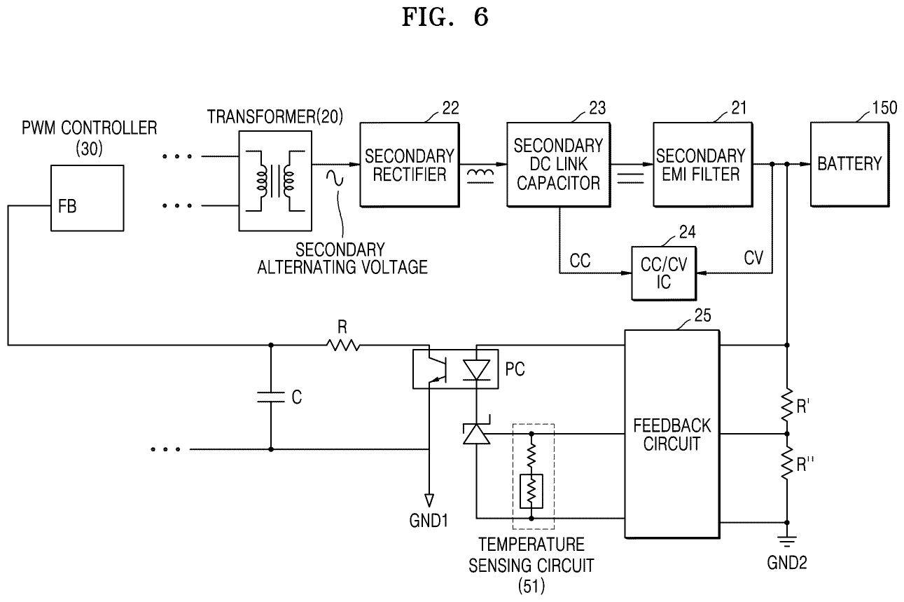

FIG. 6 is a circuit diagram in which a temperature sensing circuit is connected to a feedback signal side of a PWM controller according to an embodiment of the disclosure.

FIG. 6 shows that a temperature sensing circuit 51 is connected to a feedback (FB) input pin, rather than to a BR input pin of the PWM controller 30. In a state in which the battery 150 is connected to the SMPS 208, the output voltage of the SMPS 208 tracks the voltage of the battery 150 based on a signal input to the feedback (FB) input pin, and thus, overvoltage protection (OVP) of the PWM controller 30 does not operate even when the temperature of a positive temperature coefficient (PTC) thermistor 511 in the temperature sensing circuit 51 changes. Thus, connecting the PTC thermistor 511, serving as the temperature sensor 52, to the feedback (FB) signal side is not desirable from the standpoint of overheating prevention. On the contrary, as illustrated in FIG. 5, in a case in which the temperature sensing circuit 50 including the temperature sensor 52 is configured to use the BR pin of the PWM controller 30 rather than the side of the feedback circuit 25, overheating prevention may be performed irrespective of the voltage of the battery 150.

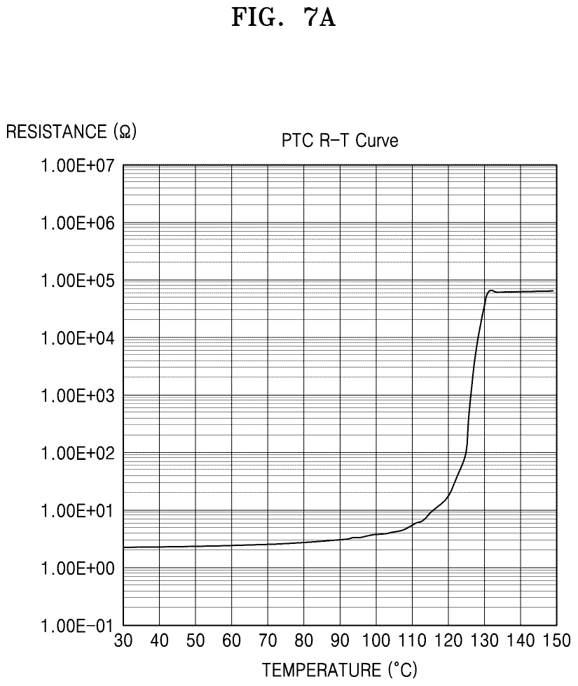

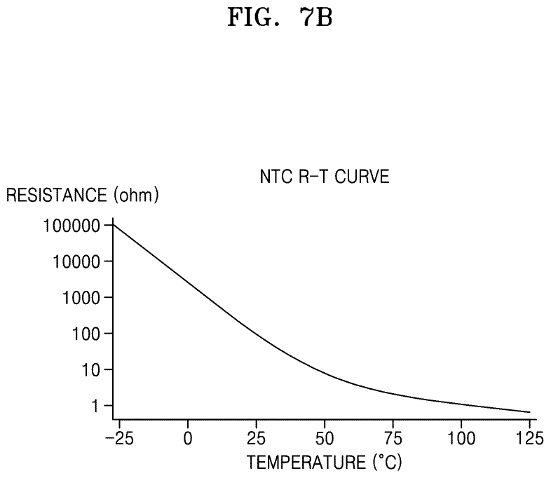

FIG. 7A is a characteristic curve graph of a thermistor as a temperature sensor used in a temperature sensing circuit, according to an embodiment of the disclosure.

FIG. 7A shows a resistance (R)-temperature (T) characteristic curve graph of a PTC thermistor 521 as the temperature sensor 52 used in the temperature sensing circuit 50. Referring to FIG. 7A, the PTC thermistor 521 has a characteristic in which its resistance increases as the temperature increases. In particular, the PTC thermistor 521 exhibits a prominent change in resistance corresponding to a change in temperature between 90 degrees Celsius and 130 degrees Celsius, and thus, it is suitable for detecting overheating based on a resistance change—a resistance increase—in the range of 90 degrees to 130 degrees Celsius. Referring to FIG. 7A, it may be seen that the PTC thermistor 521 has a value of approximately 20Ω at 120 degrees Celsius and a value of approximately 30 kΩ at 130 degrees Celsius.

The characteristics of the PTC thermistor 521 according to FIG. 7A are merely an example, and PTC thermistors having other resistance values in other temperature ranges may be used as needed.

FIG. 7B is a characteristic curve graph of a thermistor as a temperature sensor used in a temperature sensing circuit, according to an embodiment of the disclosure.

FIG. 7B shows a resistance (R)-temperature (T) characteristic curve graph of a negative temperature coefficient (NTC) thermistor 522 as the temperature sensor 52 used in the temperature sensing circuit 50. Referring to FIG. 7B, the NTC thermistor 522 has a characteristic in which its resistance decreases as the temperature increases. In particular, the NTC thermistor 522 exhibits a substantially uniform change in resistance corresponding to a change in temperature between −25 degrees Celsius and 125 degrees Celsius, and thus, it is suitable for detecting overheating based on a resistance change—a resistance decrease—in the range of −25 degrees to 125 degrees Celsius. For example, the NTC thermistor 522 may have a resistance value of 100 £ at 25 degrees Celsius and a resistance value of 1Ω at 100 degrees Celsius.

The characteristics of the NTC thermistor 522, according to FIG. 7B, are merely an example, and NTC thermistors having other resistance values in the corresponding temperature range may be used as needed.

FIG. 8 is a configuration diagram of an SMPS including a temperature sensing circuit, according to an embodiment of the disclosure.

Referring to FIG. 8, a DC input voltage 550 established by the DC link capacitor 13 has its voltage divided by R1 501, R3 503, and the PTC thermistor 521, which serves as a temperature sensor. When the input power source 10 is a 220-V AC voltage, the rectified and smoothed DC input voltage 550 may be 310 V. In an embodiment, R1 501 and R3 503 are divider resistors, which, together with the temperature sensor 52, cause the DC input voltage 550 established by the DC link capacitor 13 to be divided in proportion to their resistance values. R1 501 and R3 503 are merely illustrated as an example, and each of R1 501 and R3 503 may be a plurality of resistors, and according to an embodiment, R3 503 may be omitted from the temperature sensing circuit 50. A circuit designer may adjust the resistance values of R1 501 and R3 503 such that the voltage input to the overheating prevention input (BR) pin of the PWM controller 30 varies, and by such adjustment of resistance values, the circuit designer may set a temperature for determining overheating of the cordless cleaner 3000 to a desired value.

In FIG. 8, according to an embodiment of the disclosure, a voltage determined by the resistance value of the PTC thermistor 521 may be input to the ‘BR’ input pin of the PWM controller 30. The BR input pin of the PWM controller 30, as described above with reference to Table 1, is an input pin that is primarily incorporated for the overheating protection function of the PWM controller 30, and relevant specifications thereof have been described above in Table 1.

For example, the PWM controller 30 may monitor the voltage input to ‘BR’, which is an input pin for sensing an input voltage, and when the input voltage is greater than or equal to a predetermined threshold voltage, the PWM controller 30 may stop its operation, thereby cutting off the output voltage of the SMPS 208. In an embodiment, stopping the operation of the PWM controller 30 may include stopping gate output to the switch 40 from a DRV output pin of the PWM controller 30. When the temperature in a vicinity of the temperature sensing circuit 50—or more precisely, the temperature sensor 52—increases and overheating occurs, the resistance of the PTC thermistor 521 included in the temperature sensing circuit 50 increases, and accordingly, the voltage input to the input pin (BR) of the PWM controller 30 increases.

In an embodiment, when the voltage input to the input pin (BR) of the PWM controller 30 is greater than or equal to a predetermined threshold voltage (e.g., 5.45 V to 5.68 V) for determining overheating, it is determined that the temperature in a vicinity of the PTC thermistor 521 is abnormally high, and the OVP function of the PWM controller 30 is activated. As the OVP function operates, the PWM controller 30 of the SMPS 208 stops the switching that operates the switch 40 via the DRV pin output, and the output voltage of the SMPS 208 is cut off. When the temperature in a vicinity of the PTC thermistor 521 is within a normal range and the operation of the switch 40 is normally performed, the DC input voltage 550 may be converted into an output AC voltage by PWM switching, and the converted output AC voltage may be stepped down or stepped up by the transformer 20 to an appropriate final output AC voltage (on a secondary side of the transformer 20). In an embodiment, when it is determined that the temperature in a vicinity of the PTC thermistor 521 is abnormally high, and the OVP function of the PWM controller 30 operates, the PWM controller 30 of the SMPS 208 stops the switching that operates the switch 40 via the DRV pin output. At this time, the output AC voltage input to the transformer 20 becomes ‘0’, and thus, the output voltage of the SMPS 208 is cut off.

In an embodiment, in FIG. 4, the processor 203 of the station 2000 may receive a signal indicating that the operation of the PWM controller 30 is stopped, as described with reference to FIG. 8—for example, a signal of stopping the output of the DRV pin—and then control operations performed in the station 2000 and the cleaner main body 1000. In an embodiment, the processor 203 of the station 2000 may provide, via the user interface 204, an output notifying the user that the cordless cleaner 3000 is currently overheating and/or provide an output of location information indicating where the overheating is occurring—a voice output or a display output. In addition, the processor 203 may inform, via the communication interface 201, the user terminal 5000 or the server 4000 that the cordless cleaner 3000 is currently overheating and/or which position within the cordless cleaner 3000 is overheating. After recognizing via the user terminal 5000 that the cordless cleaner 3000 is overheating and that the overheating prevention function has operated, the user may transmit, to the cordless cleaner 3000, a separate control command—for example, a command to cut off the input voltage of the cordless cleaner 3000. The user may recognize at which point in the cordless cleaner 3000 the overheating is occurring and then take follow-up measures (e.g., product disassembly or requesting after-sales service (AS)) in response thereto.

In an embodiment, in a case in which the temperature sensing circuit 50 is absent in the circuit of the SMPS 208 according to FIG. 8, the resistance values of R1 501 and R3 503 both included in the circuit for sensing the DC input voltage 550 may be 18.8 MΩ and 228 kΩ, respectively. However, in an embodiment, in a case in which the PTC thermistor 521, serving as the temperature sensor 52, is included, R1 501 may be 4 MΩ, and R3 503 may be 47 kΩ. In an embodiment, by varying the resistance values of R1 501 and R3 503, the voltage input to the input pin (BR) for sensing the input voltage of the PWM controller 30 may be varied, and this also means that the circuit designer may freely set a temperature that is determined as ‘overheating’.

In the above example, when R1 501 is 4 MΩ and R3 503 is 47 kΩ, and the PTC thermistor 521 as illustrated in FIG. 7A is used, the resistance value of the PTC thermistor 521 during normal operation is almost negligibly small, and thus, the voltage measured at the BR input pin is 3.6 V (310 V*47 kΩ/(4 MΩ+47 kΩ)=3.6 V). On the contrary, when the temperature in a vicinity of the PTC thermistor 521 increases to approximately 130 degrees Celsius, the resistance value of the PTC thermistor 521 is 30 kΩ, and thus, the voltage input to the BR input pin is 5.85 V (310 V*(47 kΩ+30 kΩ)/(4 MΩ+47 kΩ+30 kΩ)=5.85 V), and the PWM controller 30 determines this as overheating based on the voltage of the BR input pin, and cuts off the gate output from the DRV output pin.

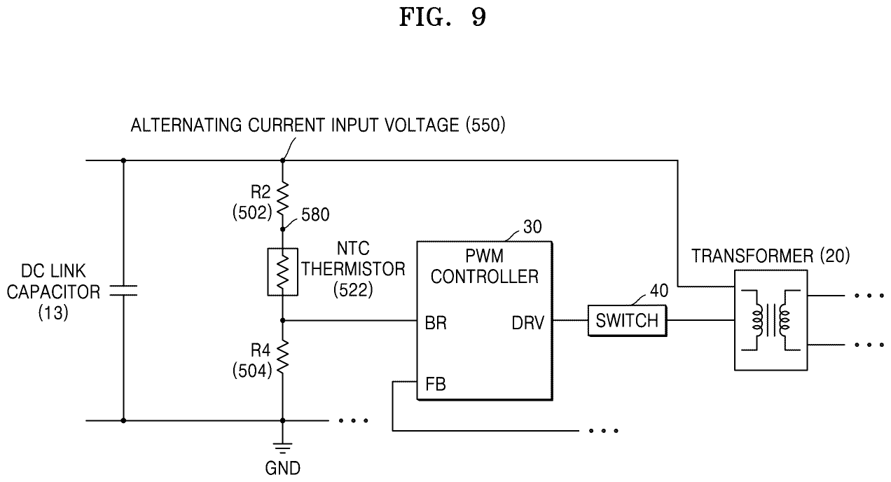

FIG. 9 is a configuration diagram of an SMPS including a temperature sensing circuit, according to an embodiment of the disclosure.

Referring to FIG. 9, the DC input voltage 550 established by the DC link capacitor 13 has its voltage divided in proportion to the resistance values of R2 502, R4 504, and the NTC thermistor 522, which serves as the temperature sensor 52. When the input power source 10 is a 220-V AC voltage, the rectified and smoothed DC input voltage 550 may be 310 V. In an embodiment, R2 502 and R4 504 are divider resistors, and the DC input voltage 550 established by the DC link capacitor 13 is divided in proportion to the magnitudes of the resistance of the temperature sensor 52, the resistance of R2 502, and the resistance of R4 504. R2 502 and R4 504 are merely illustrated as an example, and each of R2 502 and R4 504 may be a plurality of resistors, and according to an embodiment, R2 502 may be omitted from the circuit. A circuit designer may adjust the resistance values of R2 502 and R4 504 such that the voltage input to the BR input pin of the PWM controller 30 varies, and by such adjustment of resistance values, the circuit designer may set a temperature for determining overheating of the cordless cleaner 3000 to a personally desired temperature.

A difference between the temperature sensing circuit 50 of FIG. 9 and that of FIG. 8 is the use of the NTC thermistor 522 as the temperature sensor 52. The NTC thermistor 522 has a characteristic in which its resistance decreases as the sensed temperature increases.

Referring to FIG. 9, according to an embodiment of the disclosure, a voltage determined by the NTC thermistor 522 may be input to the ‘BR’ input pin of the PWM controller 30. For example, the PWM controller 30 may monitor the voltage input to ‘BR’, which is an input pin, and when the input voltage is greater than or equal to a predetermined threshold voltage for determining that overheating has occurred, the PWM controller 30 may stop its operation, thereby cutting off the output voltage of the SMPS 208. In an embodiment, stopping the operation of the PWM controller 30 may include stopping gate output from a DRV pin of the PWM controller 30. When the temperature in a vicinity of the temperature sensing circuit 50—or more precisely, the temperature sensor 52—increases and overheating occurs, the resistance of the NTC thermistor 522 included in the temperature sensing circuit 50 decreases, and accordingly, the voltage input to the input pin (BR) for sensing the input voltage of the PWM controller 30 increases. In an embodiment, when the voltage input to the input pin (BR) of the PWM controller 30 is greater than or equal to a predetermined threshold voltage (e.g., 5.45 V to 5.68 V) for determining that overheating has occurred, it is determined that the temperature in a vicinity of the NTC thermistor 522 is abnormally high, and the OVP function is activated. As the OVP function operates, the PWM controller 30 of the SMPS 208 stops the switching that operates the switch 40, and the output voltage of the SMPS 208 is cut off.

In an embodiment, in FIG. 4, the processor 203 of the station 2000 may receive a signal of stopping the operation of the PWM controller 30 is stopped, as described above with reference to FIG. 9, and control operations performed in the station 2000 and the cleaner main body 1000. For example, the processor 203 of the station 2000 may provide, via the user interface 204, an output notifying the user that the cordless cleaner 3000 is currently overheating-a voice output or a display output. In addition, the processor 203 may inform, via the communication interface 201, the user terminal 5000 or the server 4000 that the cordless cleaner 3000 is currently overheating. After recognizing via the user terminal 5000 that the cordless cleaner 3000 is overheating and that the overheating prevention function has operated, the user may transmit a separate control command—for example, a command to cut off the input voltage of the cordless cleaner 3000. In an embodiment, the processor 203 may inform, via the communication interface 201, the user terminal 5000 or the server 4000 about which point of the cordless cleaner 3000 is currently overheating. After recognizing via the user terminal 5000 that the cordless cleaner 3000 is overheating and that the overheating prevention function has operated, the user may transmit a separate control command—for example, a command to cut off the input voltage of the cordless cleaner 3000. In addition, the user may recognize at which point in the cordless cleaner 3000 the overheating is occurring and then take follow-up measures (e.g., product disassembly or requesting after-sales service (AS)) in response thereto.

In an embodiment according to FIG. 9, in a case in which the NTC thermistor 522, serving as the temperature sensor 52, is included, R2 502 may be 2.46 MΩ and R4 504 may be 47 kΩ. In an embodiment, by varying the resistance values of R2 502 and R4 504, the voltage input to the input pin (BR) for sensing the input voltage of the PWM controller 30 may be varied, and this also means that the circuit designer may freely set a temperature that is determined as ‘overheating’.

In the above example, when R2 502 is 2.46 MΩ and R4 504 is 47 kΩ, and the resistance of the NTC thermistor 522 during normal operation is approximately 300 kΩ, the voltage of the BR input pin is 55.2 V (310 V*47 kΩ/(2.46 MΩ+300 kΩ+47 kΩ)=5.2V). On the contrary, when the temperature in a vicinity of the NTC thermistor 522 increases to approximately 125 degrees Celsius, the resistance value of the NTC thermistor 522 is approximately 0.2Ω, and thus, the voltage of the BR input pin is 5.81 V (310 V*(47 kΩ)/(2.46 MΩ+0.2 Ω+47 kΩ)=5.81 V), and the PWM controller 30 may determine this state as overheating and thus cut off the gate output from the DRV output pin.

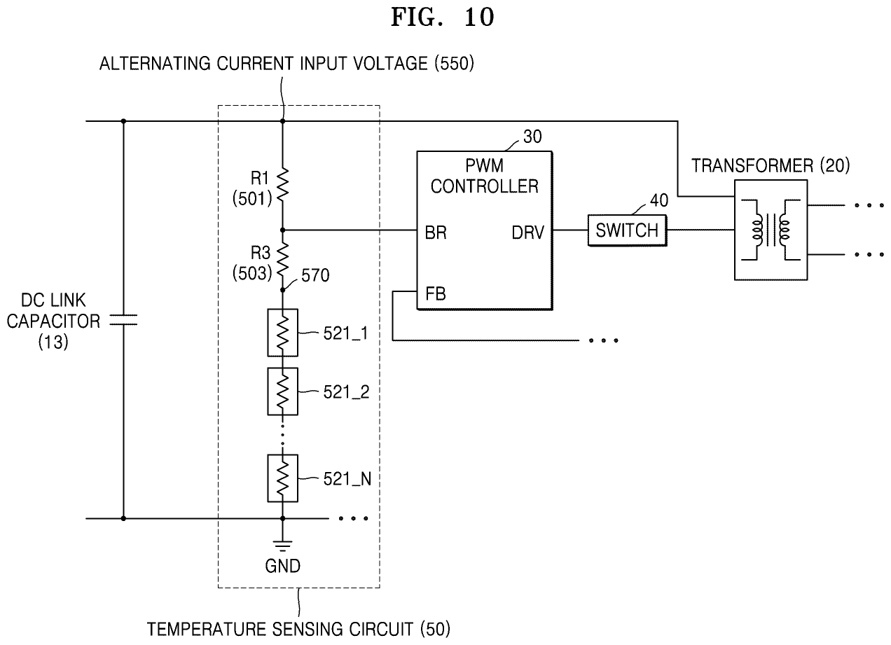

FIG. 10 is a configuration diagram of an SMPS including a temperature sensing circuit, according to an embodiment of the disclosure.

Referring to FIG. 10, it may be confirmed that a plurality of temperature sensors are connected in series, according to an embodiment of the disclosure. When compared with FIG. 8, a difference is that the temperature sensing circuit 50 of FIG. 10 includes a plurality of temperature sensors. For the temperature sensor 52, a PTC thermistor was used. In an embodiment, a plurality of PTC thermistors 521_1, 521_2, . . . , 521_N (where N is a positive integer greater than or equal to 2) may be connected to R3 503 in series.

Referring to FIG. 10, the DC input voltage 550 established by the DC link capacitor 13 has its voltage divided in proportion to the resistance values of the divider resistors R1 501, R3 503, and the plurality of PTC thermistors 521_1, 521_2, . . . , 521_N serving as temperature sensors. R1 501 and R3 503 are merely illustrated as an example, and each of R1 501 and R3 503 may be a plurality of resistors, and according to an embodiment, R3 503 may be omitted from the circuit. A product designer may adjust the resistance values of R1 501 and R3 503 such that the voltage input to the PWM controller 30 varies, and by such adjustment of resistance values, the product designer may set differently a temperature for determining overheating of the cordless cleaner 3000.

In FIG. 10, according to an embodiment of the disclosure, a voltage determined by a variation in resistance of the plurality of PTC thermistors 521_1, 521_2, . . . , 521_N may be input to the ‘BR’ input pin of the PWM controller 30.

For example, the PWM controller 30 may monitor the voltage input to ‘BR’, which is an input pin for sensing an input voltage, and when the input voltage is greater than or equal to a predetermined threshold voltage for determining that overheating has occurred, the PWM controller 30 may stop its operation, thereby cutting off the output voltage of the SMPS 208. In an embodiment, stopping the operation of the PWM controller 30 may include stopping gate output from a DRV pin of the PWM controller 30. When the temperature in a vicinity of the temperature sensing circuit 50—or more precisely, at least one of the plurality of PTC thermistors 521_1, 521_2, . . . , 521_N-increases and overheating occurs, the resistance of at least one of the plurality of PTC thermistors 521_1, 521_2, . . . , 521_N included in the temperature sensing circuit 50 increases, and accordingly, the voltage input to the input pin (BR) for sensing the input voltage of the PWM controller 30 increases. In an embodiment, when the voltage input to the input pin (BR) for sensing the input voltage of the PWM controller 30 is greater than or equal to a predetermined threshold voltage (e.g., 5.45 V to 5.68 V) for determining overheating, it is determined that the temperature at a point where at least one of the plurality of PTC thermistors 521_1, 521_2, . . . , 521_N is located is abnormally high, and the OVP function inherent to the PWM controller 30 operates. As the OVP function operates, the PWM controller 30 of the SMPS 208 stops the switching that operates the switch 40, and the output voltage of the SMPS 208 is cut off.

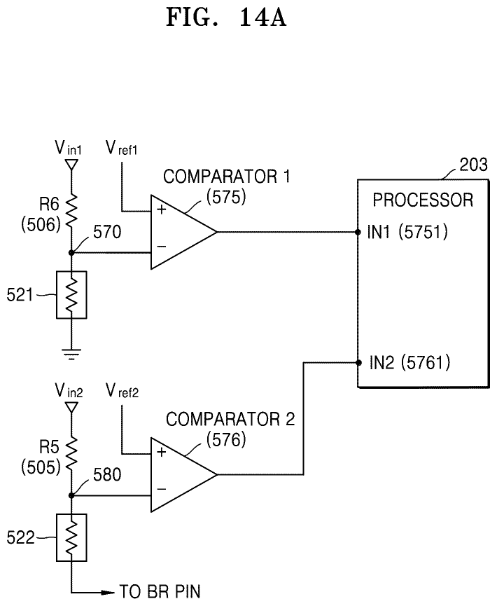

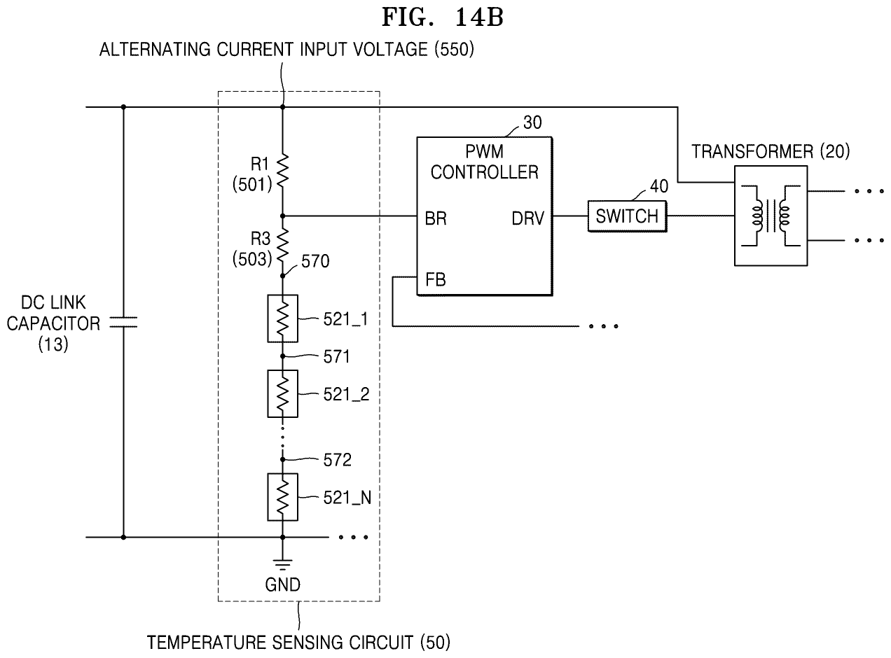

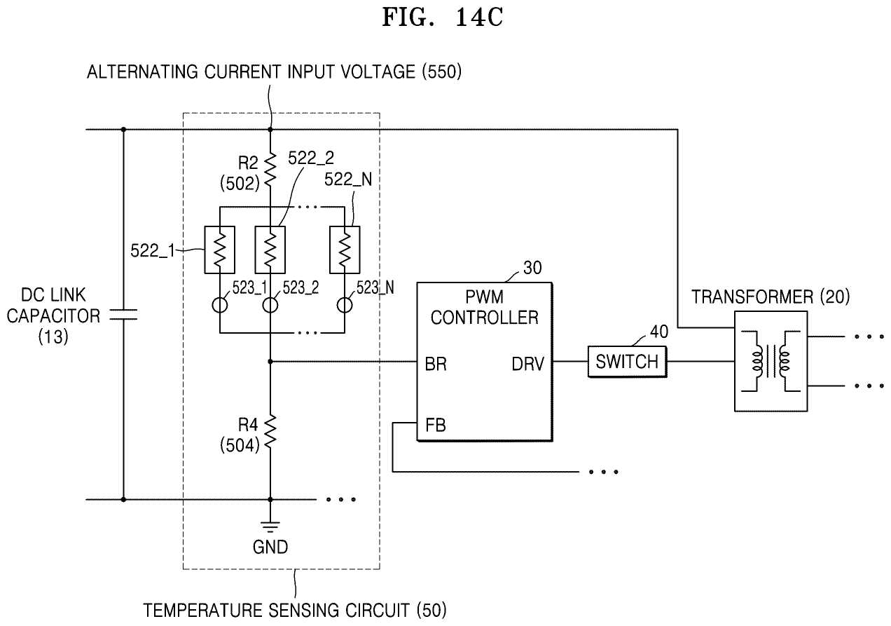

In an embodiment, in FIG. 4, the processor 203 of the station 2000 may receive a signal indicating that the operation of the PWM controller 30 is stopped, as described above with reference to FIG. 10, and control operations performed in the station 2000 and the cleaner main body 1000. For example, the processor 203 of the station 2000 may provide, via the user interface 204, an output notifying the user that the cordless cleaner 3000 is currently overheating-a voice output or a display output. In addition, the processor 203 may inform, via the communication interface 201, the user terminal 5000 or the server 4000 that the cordless cleaner 3000 is currently overheating. After recognizing via the user terminal 5000 that the cordless cleaner 3000 is overheating and that the overheating prevention function has operated, the user may transmit a separate control command—for example, a command to cut off the input voltage of the cordless cleaner 3000. In an embodiment, the processor 203 may inform, via the communication interface 201, the user terminal 5000 or the server 4000 about which point of the cordless cleaner 3000 is currently overheating. After recognizing via the user terminal 5000 that the cordless cleaner 3000 is overheating and that the overheating prevention function has operated, the user may transmit a separate control command—for example, a command to cut off the input voltage of the cordless cleaner 3000. In addition, the user may recognize at which point in the cordless cleaner 3000 the overheating is occurring and then take follow-up measures (e.g., product disassembly or requesting after-sales service (AS)) in response thereto. At which point overheating occurs will be described below with reference to FIG. 14B.

In an embodiment, in the circuit diagram of the SMPS 208 according to FIG. 10, the resistance value of R1 501 and the resistance value of R3 503 may vary depending on the number of the plurality of PTC thermistors 521_1, 521_2, . . . , 521_N. In an embodiment, in a case in which two PTC thermistors 521 are included, R1 501 may be 4 MΩ, and R3 503 may be 47 kΩ. In an embodiment, by varying the resistance values of R1 501 and R3 503, the voltage input to the input pin (BR) for sensing the input voltage of the PWM controller 30 may be varied, and this also means that the circuit designer may freely set a temperature that is determined as ‘overheating’.

In the above example, in a case in which R1 501 is 4 MΩ and R3 503 is 47 kΩ, and the PTC thermistor 521 as illustrated in FIG. 7A is used, even when a plurality of PTC thermistors 521_1, 521_2, . . . , 521_N are connected in series, the resistance values of the plurality of PTC thermistors 521_1, 521_2, . . . , 521_N during normal operation are almost negligible, and thus, the voltage input to the BR input pin is approximately 3.6 V (310 V*47 kΩ/(4 MΩ+47 kΩ)=3.6 V). On the contrary, when the temperature at a point where any one of the plurality of PTC thermistors 521_1, 521_2, . . . , 521_N is located reaches approximately 130 degrees Celsius, the resistance value of the PTC thermistor in the vicinity that has increased to approximately 130 degrees Celsius among the plurality of PTC thermistors 521_1, 521_2, . . . , 521_N is approximately 30 kΩ, and thus, the voltage of the BR input pin is 5.85 V (310 V*(47 kΩ+30 kΩ)/(4 MΩ+47 kΩ+30 kΩ)=5.85 V). The PWM controller 30 may determine this state as overheating and thus cut off the gate output from the DRV output pin.

Although it will be described below with reference to FIG. 14A, according to an embodiment, by comparing the voltage of each of the plurality of PTC thermistors 521_1, 521_2, . . . , 521_N with a comparator and having the processor 203 read this output value, it may be determined at which of the points where the plurality of PTC thermistors 521_1, 521_2, . . . , 521_N are located overheating has occurred.

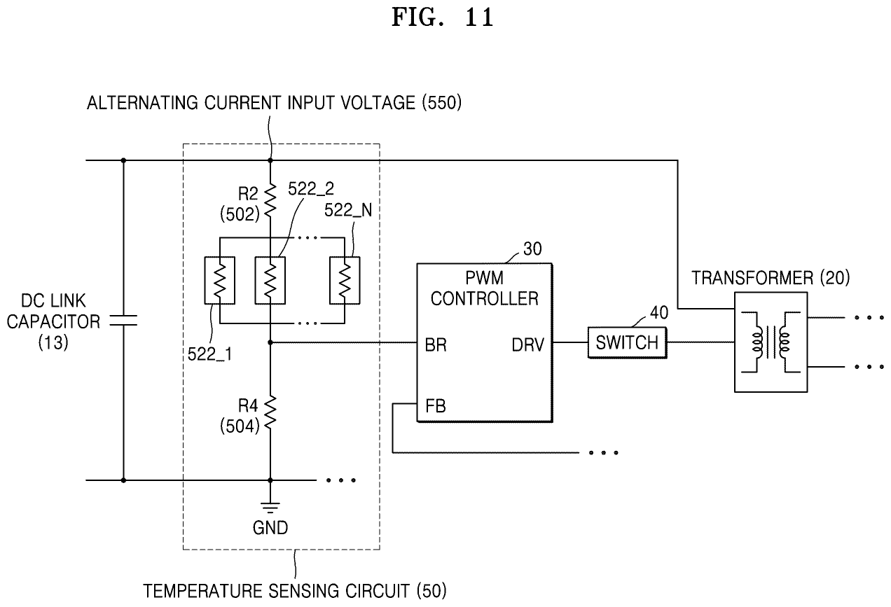

FIG. 11 is a configuration diagram of an SMPS including a temperature sensing circuit, according to an embodiment of the disclosure.

Referring to FIG. 11, with respect to the DC input voltage 550 established by the DC link capacitor 13, in a case in which the input power source 10 is a 220-V AC voltage, the rectified and smoothed DC input voltage 550 may be 310 V. In an embodiment, R2 502 and R4 504 are divider resistors, and the DC input voltage 550 established by the DC link capacitor 13 is divided in proportion to the resistance values of the divider resistors and a plurality of temperature sensors. R2 502 and R4 504 are merely illustrated as an example, and each of R2 502 and R4 504 may be a plurality of resistors, and according to an embodiment, R2 502 may be omitted from the circuit. A circuit designer may adjust the resistance values of R2 502 and R4 504 such that the voltage input to the BR input pin of the PWM controller 30 varies, and by such adjustment of resistance values, the circuit designer may set a temperature for determining overheating of the cordless cleaner 3000 to a personally desired temperature.

A difference between the temperature sensing circuit 50 of FIG. 11 and that of FIG. 9 is the use of a plurality of NTC thermistors 522_1, 522_2, . . . , 522_N (where N is a positive integer greater than or equal to 2) as temperature sensors 52. The plurality of NTC thermistors 522_1, 522_2, . . . , 522_N may be connected in parallel, and when the temperature sensed at a point of at least one of the plurality of NTC thermistors 522_1, 522_2, . . . , 522_N connected in parallel increases, the resistance of the corresponding NTC thermistor decreases, and thus, the resistance across the plurality of NTC thermistors 522_1, 522_2, . . . , 522_N connected in parallel may decrease.

In FIG. 11, according to an embodiment of the disclosure, a voltage determined by the plurality of NTC thermistors 522_1, 522_2, . . . , 522_N may be input to the ‘BR’ input pin of the PWM controller 30. For example, the PWM controller 30 may monitor the voltage input to ‘BR’, which is an input pin for sensing an input voltage, and when input voltage is greater than or equal to a predetermined threshold voltage for determining that overheating has occurred, the PWM controller 30 may stop its operation, thereby cutting off the output voltage of the SMPS 208. In an embodiment, stopping the operation of the PWM controller 30 may include stopping gate output from a DRV pin of the PWM controller 30. When the temperature in a vicinity of the temperature sensing circuit 50—or more precisely, at least one of the plurality of NTC thermistors 522_1, 522_2, . . . , 522_N-increases and overheating occurs, the resistance of at least one of the plurality of NTC thermistors 522_1, 522_2, . . . , 522_N decreases, and accordingly, the voltage input to the input pin (BR) for sensing the input voltage of the PWM controller 30 increases. In an embodiment, when the voltage input to the input pin (BR) for sensing the input voltage of the PWM controller 30 is greater than or equal to than a predetermined threshold voltage (e.g., 5.45 V to 5.68 V) for determining overheating, it is determined that the temperature at a point where at least one of the plurality of NTC thermistors 522_1, 522_2, . . . , 522_N is located is abnormally high, and an AC input voltage OVP function inherent to the PWM controller 30 is activated. As the OVP function operates, the PWM controller 30 of the SMPS 208 stops the switching that operates the switch 40, and the output voltage of the SMPS 208 is cut off.

In an embodiment, in FIG. 4, the processor 203 of the station 2000 may receive a signal indicating that the operation of the PWM controller 30 is stopped, as described above with reference to FIG. 11, and control operations performed in the station 2000 and the cleaner main body 1000. For example, the processor 203 of the station 2000 may provide, via the user interface 204, an output notifying the user that the cordless cleaner 3000 is currently overheating—a voice output or a display output. In addition, the processor 203 may inform, via the communication interface 201, the user terminal 5000 or the server 4000 that the cordless cleaner 3000 is currently overheating. After recognizing via the user terminal 5000 that the cordless cleaner 3000 is overheating and that the overheating prevention function has operated, the user may transmit a separate control command—for example, a command to cut off the input voltage of the cordless cleaner 3000. In an embodiment, the processor 203 may inform, via the communication interface 201, the user terminal 5000 or the server 4000 about which point of the cordless cleaner 3000 is currently overheating. After recognizing via the user terminal 5000 that the cordless cleaner 3000 is overheating and that the overheating prevention function has operated, the user may transmit a separate control command—for example, a command to cut off the input voltage of the cordless cleaner 3000. In addition, the user may recognize at which point in the cordless cleaner 3000 the overheating is occurring and then take follow-up measures (e.g., product disassembly or requesting after-sales service (AS)) in response thereto. A method of recognizing at which point overheating occurs will be described again below with reference to FIG. 14C.

In an embodiment, according to FIG. 11, in a case in which the plurality of NTC thermistors 522_1, 522_2, . . . , 522_N are included, R2 502 may be 2.46 MΩ, and R4 504 may be 47 kΩ. In an embodiment, by varying the resistance values of R2 502 and R4 504, the voltage input to the input pin (BR) for sensing the input voltage of the PWM controller 30 may be varied, and this also means that the circuit designer may freely set a temperature that is determined as ‘overheating’.

In the above example, assume that the temperature sensor 52 includes two NTC thermistors. When R2 502 is 2.46 MΩ and R4 504 is 47 kΩ, and the resistance of the plurality of NTC thermistors 522_1 and 522_2 connected in parallel during normal operation is approximately 150 kΩ, the voltage of the BR input pin is 5.48 V (310 V*47 kΩ/(2.46 MΩ+150 kΩ+47 kΩ)=5.48 V). On the contrary, when the temperature at a point where at least one of the plurality of NTC thermistors 522_1 and 522_2 is located increases to approximately 125 degrees Celsius, the resistance value of the plurality of NTC thermistors 522_1 and 522_2 is almost negligible (approximately 0.2Ω), and thus, the voltage of the BR input pin is 5.81 V (310 V*47 kΩ/(2.46 MΩ+0.2 Ω+47 kΩ)=5.81 V), and the PWM controller 30 may determine this state as overheating and thus cut off the gate output from the DRV output pin.

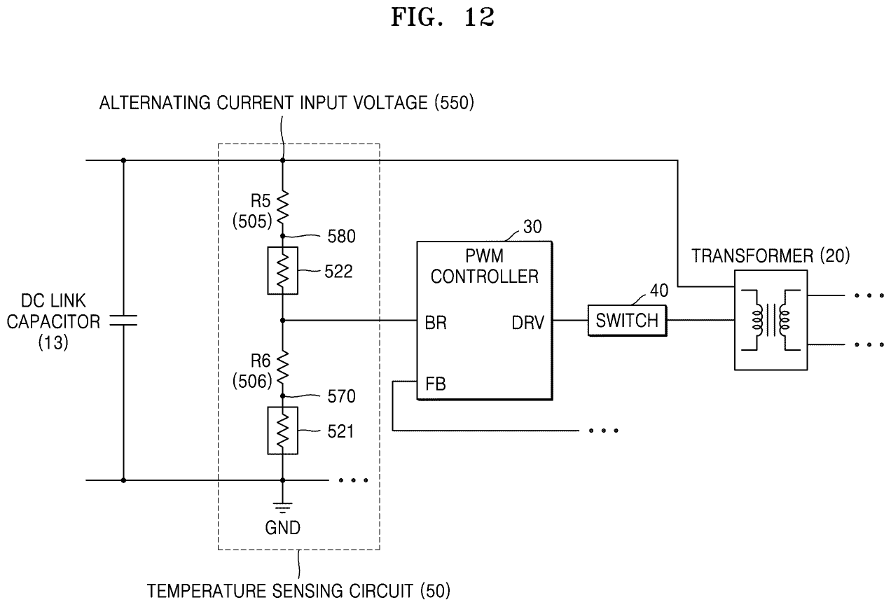

FIG. 12 is a configuration diagram of an SMPS including a temperature sensing circuit, according to an embodiment of the disclosure.

Referring to FIG. 12, the DC input voltage 550 established by the DC link capacitor 13 has its voltage divided in proportion to the resistance values of R5 505, R6 506, and the PTC thermistor 521 and NTC thermistor 522 serving as temperature sensors. R5 505 and R6 506 are merely illustrated as an example, and each of R5 505 and R6 506 may include a plurality of resistors. A circuit designer may adjust the resistance values of R5 505 and R6 506 such that the voltage input to the PWM controller 30 varies, and by such adjustment of resistance values, the circuit designer may set differently a temperature for determining overheating of the cordless cleaner 3000.

In FIG. 12, according to an embodiment of the disclosure, a voltage determined by a change in the resistance of the PTC thermistor 521 and/or the NTC thermistor 522 may be input to the ‘BR’ input pin of the PWM controller 30. For example, the PWM controller 30 may monitor the voltage input to ‘BR’, which is an input pin for sensing an input voltage, and when the input voltage is greater than or equal to a predetermined threshold voltage corresponding to overheating, the PWM controller 30 may stop its operation, thereby cutting off the output voltage of the SMPS 208. In an embodiment, stopping the operation of the PWM controller 30 may include stopping gate output from a DRV pin of the PWM controller 30. When the temperature in a vicinity of the PTC thermistor 521 and/or the NTC thermistor 522 in the temperature sensing circuit 50 increases and overheating occurs, the resistance of the PTC thermistor 521 increases or the resistance of the NTC thermistor 522 decreases, and accordingly, the voltage input to the input pin (BR) for sensing the input voltage of the PWM controller 30 increases. In an embodiment, when the voltage input to the input pin (BR) for sensing the input voltage of the PWM controller 30 is greater than or equal to a predetermined threshold voltage (e.g., 5.45 V to 5.68 V) that is determined as overheating, it is determined that the temperature in a vicinity of the PTC thermistor 521 and/or the NTC thermistor 522 is abnormally high, and the OVP function is activated in the PWM controller 30. As the OVP function operates, the PWM controller 30 of the SMPS 208 stops the switching that operates the switch 40, and the output voltage of the SMPS 208 is cut off.

In an embodiment, in FIG. 4, the processor 203 of the station 2000 may receive a signal indicating that the operation of the PWM controller 30 is stopped, as described above with reference to FIG. 12, and control operations performed in the station 2000 and the cleaner main body 1000. For example, the processor 203 of the station 2000 may provide, via the user interface 204, an output notifying the user that the cordless cleaner 3000 is currently overheating-a voice output or a display output. In addition, the processor 203 may inform, via the communication interface 201, the user terminal 5000 or the server 4000 that the cordless cleaner 3000 is currently overheating. After recognizing via the user terminal 5000 that the cordless cleaner 3000 is overheating and that the overheating prevention function has operated, the user may transmit a separate control command—for example, a command to cut off the input voltage of the cordless cleaner 3000. In an embodiment, the processor 203 may inform, via the communication interface 201, the user terminal 5000 or the server 4000 about which point of the cordless cleaner 3000 is currently overheating. After recognizing via the user terminal 5000 that the cordless cleaner 3000 is overheating and that the overheating prevention function has operated, the user may transmit a separate control command—for example, a command to cut off the input voltage of the cordless cleaner 3000. In addition, the user may recognize at which point in the cordless cleaner 3000 the overheating is occurring and then take follow-up measures (e.g., product disassembly or requesting after-sales service (AS)) in response thereto.

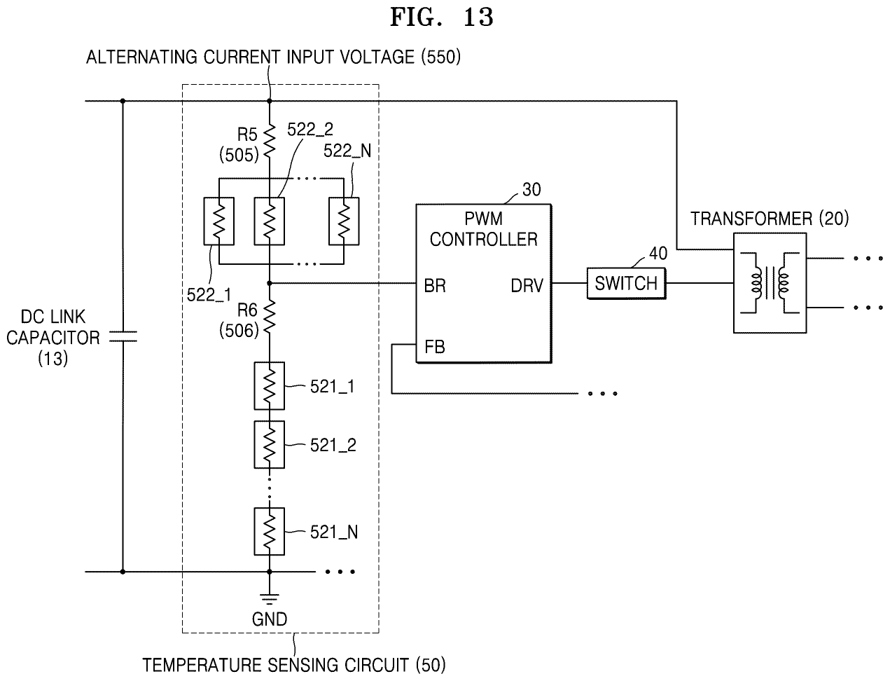

FIG. 13 is a configuration diagram of an SMPS including a temperature sensing circuit, according to an embodiment of the disclosure.

Referring to FIG. 13, the DC input voltage 550 established by the DC link capacitor 13 has its voltage divided in proportion to the resistance values of the divider resistors R5 505, R6 506, and the plurality of PTC thermistors 521_1, 521_2, . . . , 521_N (where N is a positive integer greater than or equal to 2) and the plurality of NTC thermistors 522_1, 522_2, . . . , 522_N (where N is a positive integer greater than or equal to 2), which serve as temperature sensors. R5 505 and R6 506 are merely illustrated as an example, and each of R5 505 and R6 506 may include a plurality of resistors. A circuit designer may adjust the resistance values of R5 505 and R6 506 such that the voltage input to the BR input pin of the PWM controller 30 varies, and by such adjustment of resistance values, the circuit designer may set differently a temperature for determining overheating of the cordless cleaner 3000.

In FIG. 13, according to an embodiment of the disclosure, a voltage determined by a change in the resistance values of the plurality of PTC thermistors 521_1, 521_2, . . . , 521_N and/or the plurality of NTC thermistors 522_1, 522_2, . . . , 522_N may be input to the ‘BR’ input pin of the PWM controller 30. For example, the PWM controller 30 may monitor the voltage input to ‘BR’, which is an input pin for sensing an input voltage, and when the input voltage is greater than or equal to a predetermined threshold voltage, the PWM controller 30 may stop its operation, thereby cutting off the output voltage of the SMPS 208. In an embodiment, stopping the operation of the PWM controller 30 may include cutting off gate output from a DRV pin of the PWM controller 30. When the temperature at a point corresponding to each of the plurality of PTC thermistors 521_1, 521_2, . . . , 521_N and/or the plurality of NTC thermistors 522_1, 522_2, . . . , 522_N in the temperature sensing circuit 50 increases and overheating occurs, the resistance of at least one of the plurality of PTC thermistors 521_1, 521_2, . . . , 521_N increases, or the resistance of at least one of the plurality of NTC thermistors 522_1, 522_2, . . . , 522_N decreases, and accordingly, the voltage input to the input pin (BR) for sensing the input voltage of the PWM controller 30 increases. In an embodiment, when the voltage input to the input pin (BR) for sensing the input voltage of the PWM controller 30 is greater than or equal to a predetermined threshold voltage (e.g., 5.45 V to 5.68 V) for determining overheating, it is determined that the temperature at a point corresponding to at least one of the plurality of PTC thermistors 521_1, 521_2, . . . , 521_N and/or the plurality of NTC thermistors 522_1, 522_2, . . . , 522_N is abnormally high, and the OVP function is activated in the PWM controller 30. As the OVP function operates, the PWM controller 30 of the SMPS 208 stops the switching that operates the switch 40, and the output voltage of the SMPS 208 is cut off.

In an embodiment, in FIG. 4, when an overheating detection operation is performed by the PWM controller 30 as described above with reference to FIG. 13, the processor 203 of the station 2000 may control operations performed in the station 2000 and the cleaner main body 1000. However, when the operation of the switch 40 of the PWM controller 30 stops, the power supply to the processor 203 may also be interrupted. Thus, in an embodiment, immediately before a voltage level (e.g., 3.96 V) that is determined as overheating via a comparator (not shown) that monitors the voltage input to the ‘BR’ pin of the PWM controller 30 (e.g., at 3.93 V), the processor 203 of the station 2000 may provide in advance, via the user interface 204, an output notifying the user that the cordless cleaner 3000 is currently overheating-such as a voice output or a display output. In addition, the processor 203 may inform, via the communication interface 201, the user terminal 5000 or the server 4000 that the cordless cleaner 3000 is currently overheating. After recognizing via the user terminal 5000 that the cordless cleaner 3000 is overheating and that the overheating prevention function has operated, the user may transmit a separate control command—for example, a command to cut off the input voltage of the cordless cleaner 3000. In an embodiment, the processor 203 may inform, via the communication interface 201, the user terminal 5000 or the server 4000 about which point of the cordless cleaner 3000 is currently overheating. After recognizing via the user terminal 5000 that the cordless cleaner 3000 is overheating and that the overheating prevention function has operated, the user may transmit a separate control command—for example, a command to cut off the input voltage of the cordless cleaner 3000. In addition, the user may recognize at which point in the cordless cleaner 3000 the overheating is occurring and then take follow-up measures (e.g., product disassembly or requesting after-sales service (AS)) in response thereto.

FIG. 14A is a block diagram illustrating detecting a position of an overheating occurrence in a temperature sensing circuit, according to an embodiment of the disclosure.

For convenience of description of FIG. 14A, reference will also be made to the temperature sensing circuit 50 of FIG. 12.

In the temperature sensing circuit 50 of FIG. 12, a midpoint between R6 506 and the PTC thermistor 521 is referred to as a P-midpoint 570. The voltage at the P-midpoint 570 represents the voltage across the PTC thermistor 521. When the P-midpoint 570 is connected to comparator 1 575, the voltage across the PTC thermistor 521 is input to comparator 1 575. A predetermined first threshold voltage Vref1, at which the PTC thermistor 521 is determined as overheating, is input to another input of comparator 1 575. The output of comparator 1 575 is applied as an input signal to IN1 5751 of the processor 203. In an embodiment, with respect to comparator 1 575, when the temperature in a vicinity of the PTC thermistor 521 becomes excessively high such that the voltage corresponding to the P-midpoint 570 is greater than or equal to the predetermined first threshold voltage Vref1, the processor 203 recognizes, based on the input signal at IN1 5751 that is the output of comparator 1 575, that overheating is occurring at the point where the PTC thermistor 521 is located.

Referring to FIG. 14A, in the temperature sensing circuit 50 of FIG. 12, an N-midpoint 580 between R5 505 and the NTC thermistor 522 represents the voltage across the NTC thermistor 522. The N-midpoint 580 is input to comparator 2 576, and a predetermined second threshold voltage Vref2, at which the NTC thermistor 522 is determined as overheating, is input to another input of comparator 2 576. The output of comparator 2 576 is applied as an input signal to IN2 5761 of the processor 203. In an embodiment, with respect to comparator 2 576, when the temperature in a vicinity of the NTC thermistor 522 becomes excessively high such that the voltage of the N-midpoint 580 is greater than or equal to the predetermined second threshold voltage Vref2, IN2 5761 of the processor 203 receives the output signal of comparator 2 576 as input. Based on the input signal applied to IN2 5761, the processor 203 recognizes that overheating is occurring at the point where the NTC thermistor 522 is located. The processor 203 that has recognized the overheating may notify, via the communication interface 201, the user terminal 5000 or a server (not shown) about the overheating. When the operation of the switch 40 of the PWM controller 30 is stopped due to overheating, the operation of the processor 203 may also be stopped, and thus, in an embodiment, by setting the predetermined first threshold voltage Vref1 and the predetermined second threshold voltage Vref2, which are input to comparator 1 575 and comparator 2 576, respectively, for determining whether the PTC thermistor 521 is overheating, to be slightly lower than an actual overheating determination threshold voltage (e.g., actual overheating determination threshold voltage-predetermined first threshold voltage=0.2 V), time may be secured to notify the user terminal 5000 or the server 4000 before the processor 203 stops its operation due to overheating.

Although a method of detecting a position of an overheating occurrence based on the temperature sensing circuit 50 according to FIG. 12 is described above with reference to FIG. 14A, this method of detecting a position of an overheating occurrence may be equally applied to all the temperature sensing circuits according to FIGS. 8 to 11 and 13.

FIG. 14B is a diagram for detecting a position of an overheating occurrence in an SMPS configuration, according to an embodiment of the disclosure.

Referring to FIG. 14B, according to FIG. 10, the voltage across each of the plurality of PTC thermistors 521_1, 521_2, . . . , 521_N (where N is a positive integer greater than or equal to 2) may be input to a comparator. For example, the first PTC thermistor 521_1 may input, as a comparator input, the voltage across a point 570 and a point 571, and similarly, the other PTC thermistors—for example, for the N-th PTC thermistor 521_N—may input, as a comparator input, the voltage across a point 572 and a ground. Another input of the comparator that receives the voltage across the point 570 and the point 571 as input may receive, as input, a predetermined threshold voltage that corresponds to the voltage across the first PTC thermistor 521_1, when overheating is determined based on a change in the resistance of the first PTC thermistor 521_1. Similarly, another input of the comparator that receives the voltage across the point 572 and the ground as input may receive, as input, a predetermined threshold voltage that corresponds to the voltage across the N-th PTC thermistor 521_N, when overheating is determined based on a change in the resistance of the N-th PTC thermistor 521_N. In this manner, by receiving the output of the comparators as input to the processor 203, it may be determined at which point among the plurality of PTC thermistors 521_1, 521_2, . . . , 521_N overheating has occurred. In an embodiment, when the processor 203 receives the output of each comparator via an analog-to-digital input port, and has a mapping table that correlates each thermistor point with each analog-to-digital input port, it may determine at which point of the cordless cleaner 3000 corresponding to each thermistor overheating has occurred.

In an embodiment, referring to FIG. 14B, the voltage across each of the plurality of PTC thermistors 521_1, 521_2, . . . , 521_N (where N is a positive integer greater than or equal to 2) with respect to the ground may be input to a comparator. For example, the first PTC thermistor 521_1 may input, as a first comparator input, the voltage across the point 570 and the ground, the second PTC thermistor 521_2 may input, as a second comparator input, the voltage across the point 571 and the ground, and similarly, the other PTC thermistors—for example, the N-th PTC thermistor 521_N—may input, as an N-th comparator input, the voltage across the point 572 and the ground. Through the respective comparison outputs of the first comparator receiving the voltage across the point 570 and the ground as input, the second comparator receiving the voltage across the point 571 and the ground as input, . . . , and the N-th comparator receiving the voltage across the point 572 and the ground as input, the processor 203 may determine at which point among the points (PTC thermistor 521_1 to PTC thermistor 521_N) overheating has occurred. For example, when there is no variation in the voltage inputs corresponding to the second comparator to the N-th comparator, but there is a variation in the voltage input corresponding to the first comparator, it may be determined, based on the output of the first comparator, that overheating has occurred at the point corresponding to 521_1. As another example, when there is no variation in the voltage inputs corresponding to the third comparator to the N-th comparator, but a variation has occurred in the voltage inputs of the first comparator and the second comparator, the processor 203 may determine that overheating has occurred at the point corresponding to 521_2.

FIG. 14C is a diagram for detecting a position of an overheating occurrence in an SMPS configuration, according to an embodiment of the disclosure.

Referring to FIG. 14C, according to FIG. 11, a current flowing through each of the plurality of NTC thermistors 522_1, 522_2, . . . , 522_N (where N is a positive integer greater than or equal to 2) may be sensed by a current sensor. To sense the current flowing through each of the plurality of NTC thermistors 522_1, 522_2, . . . , 522_N, a plurality of current sensors 523_1, 523_2, . . . , 523_N may be connected in series to the plurality of NTC thermistors 522_1, 522_2, . . . , 522_N. The resistance of an NTC thermistor decreases as the sensed temperature increases, and thus, in a case in which the plurality of NTC thermistors 522_1, 522_2, . . . , 522_N are connected in parallel, the current flowing through an NTC thermistor whose temperature is increasing may increase. By detecting this increasing current by using at least one of the plurality of current sensors 523_1, 523_2, . . . , 523_N and then receiving this as input to the processor 203, it may be determined at which point among the plurality of NTC thermistors 522_1, 522_2, . . . , 522_N overheating has occurred. In an embodiment, when the processor 203 receives the output of the plurality of current sensors 523_1, 523_2, . . . , 523_N via analog-to-digital input ports, and has a mapping table that correlates each thermistor point with each analog-to-digital input port, the processor 203 may determine overheating occurrence points of the cordless cleaner 3000 corresponding to each of the plurality of NTC thermistors 522_1, 522_2, . . . , 522_N.

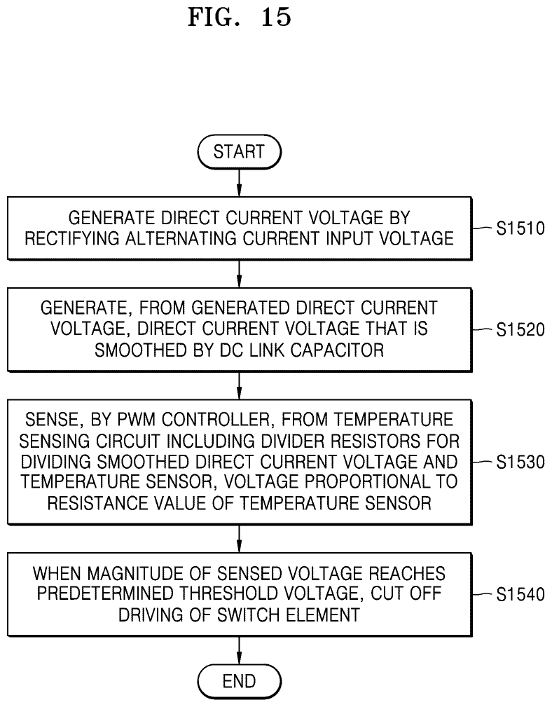

FIG. 15 is a flowchart for performing overheating prevention for a cordless cleaner by using a temperature sensing circuit provided in an SMPS, according to an embodiment of the disclosure.

Referring to FIG. 15, in operation S1510, the SMPS 208 generates a DC voltage by rectifying an AC input voltage via the rectifier 12. In operation S1520, the SMPS 208 generates, from the generated DC voltage, a DC voltage that is smoothed by the DC link capacitor 13. When the AC input voltage is 220 V, the DC voltage, which is rectified via the rectifier and then smoothed, may be 310 V.

In operation S1530, the PWM controller 30 of the SMPS 208 may sense, from the temperature sensing circuit 50 including divider resistors for dividing the smoothed DC voltage and the temperature sensor 52, a voltage proportional to the resistance value of the temperature sensor 52. The PWM controller 30 may detect whether a voltage between the temperature sensor 52 and the divider resistor, corresponding to a change in the resistance of the temperature sensor 52, is greater than or equal to a predetermined threshold voltage that is determined as overheating. The temperature sensor 52 may use the PTC thermistor 521 and/or the NTC thermistor 522.

In operation S1540, when the magnitude of the sensed voltage reaches the predetermined threshold voltage that is determined as overheating, the PWM controller 30 may perform an overheating prevention operation for preventing overheating. In an embodiment, the overheating prevention operation may include cutting off driving of a switch element.

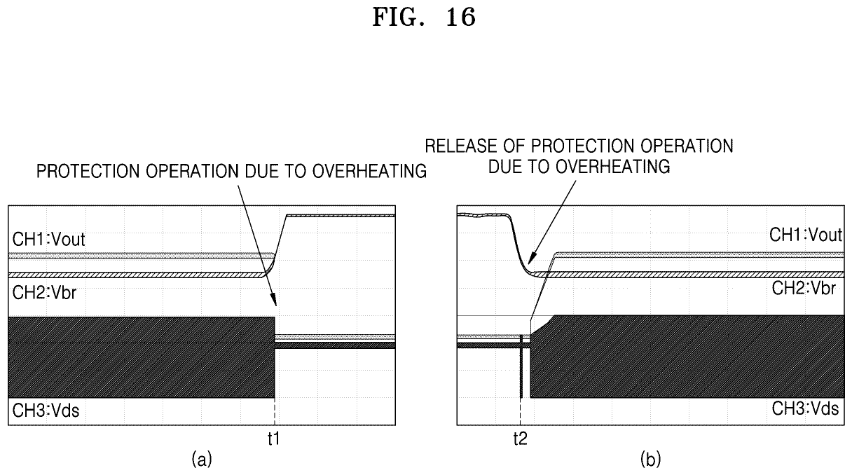

FIG. 16 is a waveform diagram illustrating an overheating protection operation according to an embodiment of the disclosure.

In FIG. 16, Vout of CH1 is the output voltage of the SMPS 208. For example, the output voltage of the SMPS 208 may be considered a 30-V DC voltage output for charging the battery 150 of the cleaner main body 1000. Vbr of CH2 may be considered the voltage input to the BR pin of the PWM controller 30. When the voltage Vbr input to the BR pin is greater than or equal to a predetermined threshold voltage for determining overheating, it may be determined that the temperature in a vicinity of the temperature sensor 52 is abnormally high, and the PWM controller 30 may cut off the gate output. Vds of CH3 may be considered the gate output of the PWM controller 30.

Referring to part (a) of FIG. 16, when the temperature sensor 52 is heated for some reason, the resistance value of the temperature sensor 52 varies—increasing in the case of the PTC thermistor 521 and decreasing in the case of the NTC thermistor 522—and at this time, Vbr increases due to the configuration of the temperature sensing circuit 50, and at a time point t1 when Vbr reaches a voltage at which the overheating protection operation is performed—i.e., greater than or equal to a predetermined threshold voltage—the ‘overheating protection operation’ is performed such that the gate output of the PWM controller 30 is cut off, causing Vds to become 0, and Vout is also cut off.

Referring to part (b) of FIG. 16, as the heat sensed by the temperature sensor 52 decreases, the resistance of the temperature sensor 52 varies-decreasing in the case of the PTC thermistor 521 and increasing in the case of the NTC thermistor 522—whereby Vbr decreases. When Vbr reaches t2, which is the point where the overheating protection operation is released—i.e., less than the predetermined threshold voltage—the gate output of the PWM controller 30 resumes, Vds turns on, and Vout also increases again, such that a 30-V DC voltage due to the normal operation of the SMPS 208 is output.

In an embodiment, in the cordless cleaner 3000, the voltage point at which the overheating protection operation is initiated and the voltage point at which the overheating protection operation is released may be the same predetermined threshold voltage. In an embodiment, in the cordless cleaner 3000, the voltage point at which the overheating protection operation is initiated and the voltage point at which the overheating protection operation is released may be different from each other. In other words, for example, when the initiation and release of the overheating protection operation are repeated within a narrow range, gate cutoff and gate output may be repeated at a high frequency, and thus, to prevent this phenomenon, a voltage point V1 at which the overheating protection operation is initiated and a voltage point V2 at which the overheating protection operation is released may be set to be different from each other (e.g., V1>V2).

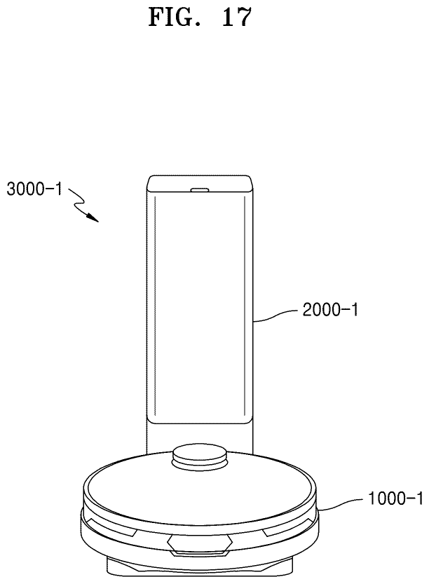

FIG. 17 is a diagram illustrating a robot cleaner as a cordless cleaner that includes a temperature sensing circuit for overheating prevention, according to an embodiment of the disclosure.

According to an embodiment of the disclosure, a cordless cleaner including the temperature sensing circuit 50 for performing an overheating prevention operation may be a robot cleaner 3000-1. The robot cleaner 3000-1 may include a cleaner main body 1000-1 configured to automatically perform cleaning while moving, and a station 2000-1 to which the cleaner main body 1000-1 may dock to perform battery charging. In an embodiment, when overheating occurs at a position where the temperature sensor 52 is installed in the cleaner main body 1000-1 or the station 2000-1 of the robot cleaner 3000-1, the operation of the SMPS 208 may be cut off according to the method of preventing overheating according to FIG. 15.

A home appliance employing a method of preventing overheating by using a temperature sensor, according to an embodiment of the disclosure, may include a DC link capacitor configured to smooth an AC input voltage, at least one divider resistor configured to divide a voltage across the DC link capacitor, and a first temperature sensor connected in series to the at least one divider resistor, and configured to divide, together with the at least one divider resistor, the voltage across the DC link capacitor, wherein a resistance of the first temperature sensor changes according to a temperature. The home appliance employing the method of preventing overheating by using a temperature sensor, according to an embodiment of the disclosure, may include a PWM controller configured to determine whether overheating has occurred, based on a change in a voltage between a first point and a ground, wherein the first point is a connection point between the at least one divider resistor and the first temperature sensor, and serves as an input to the PWM controller. The home appliance employing the method of preventing overheating by using a temperature sensor, according to an embodiment of the disclosure, may include a switch whose switching is cut off by the PWM controller in response to the PWM controller determining that the overheating has occurred, and a transformer configured to convert an output alternating current voltage generated according to a switching operation of the switch.

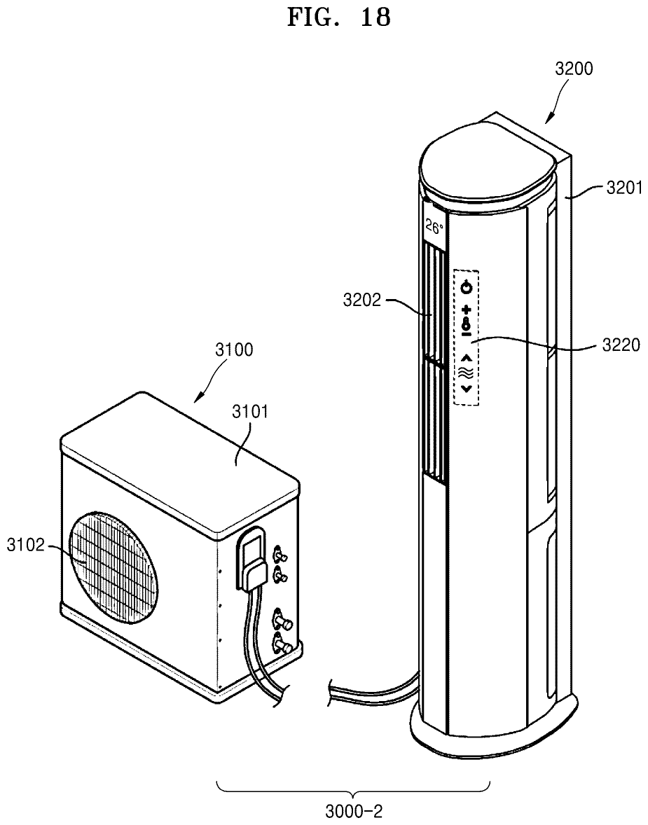

FIG. 18 is a diagram illustrating an air conditioner as a home appliance that includes a temperature sensing circuit for overheating prevention, according to an embodiment of the disclosure.

An air conditioner 3000-2 according to an embodiment of the disclosure may, for cooling of an air-conditioned space that is a target of air conditioning, absorb heat from the air-conditioned space (hereinafter referred to as an “indoor space”) and release the heat to an exterior of the air-conditioned space (hereinafter referred to as an “outdoor space”). In addition, the air conditioner 3000-2 may, for heating of the indoor space, absorb heat from the outdoor space and release the heat into the indoor space.

The air conditioner 3000-2 may include one or more outdoor units 3100 installed in the outdoor space and one or more indoor units 3200 installed in the indoor space. The outdoor unit 3100 may be electrically connected to the indoor unit 3200. For example, a user may input, via a user interface panel 3220, information (or a command) for controlling the indoor unit 3200, and the outdoor unit 3100 may operate in response to a user input to the indoor unit 3200.

The outdoor unit 3100 may be fluidically connected to the indoor unit 3200 via a refrigerant pipe.

The outdoor unit 3100 is provided in the outdoor space. The outdoor unit 3100 may perform heat exchange between a refrigerant and outdoor air by using a phase change of the refrigerant (e.g., evaporation or condensation). At this time, the heat exchange may be performed via an outdoor heat exchanger included in the outdoor unit 3100. For example, while the refrigerant is condensing in the outdoor unit 3100, the refrigerant may release heat to the outdoor air. While the refrigerant is evaporating in the outdoor unit 3100, the refrigerant may absorb heat from the outdoor air.

The indoor unit 3200 is provided in the indoor space. The indoor unit 3200 may perform heat exchange between a refrigerant and indoor air by using a phase change of the refrigerant (e.g., evaporation or condensation). At this time, the heat exchange may be performed via an indoor heat exchanger included in the indoor unit 3200. For example, while the refrigerant is evaporating in the indoor unit 3200, the refrigerant may absorb heat from the indoor air, and the indoor space may be cooled. While the refrigerant is condensing in the indoor unit 3200, the refrigerant may release heat to the indoor air, and the indoor space may be heated. The air conditioner 3000-2 may include a compressor, an outdoor heat exchanger, an expansion device, and an indoor heat exchanger. The air conditioner 3000-2 may include a refrigerant pipe connecting the compressor, the outdoor heat exchanger, the expansion device, and the indoor heat exchanger.

The indoor unit 3200 of the air conditioner 3000-2 may include the user interface panel 3220 capable of displaying operation information about the air conditioner 3000-2 and receiving a command from the user. A display unit of the user interface panel 3220 may receive information about the operation of the air conditioner 3000-2 from a processor that controls the operation of the air conditioner 3000-2, and display information corresponding to the received information. The display unit may include an indicator that displays a type of operation of the air conditioner 3000-2 selected by the user, whether the indoor unit 3200 is powered on or off, and the like. The indicator may include, for example, an LCD panel, an LED panel, or a plurality of LEDs.

The outdoor unit 3100 includes an outdoor unit main body 3101 that forms an exterior of the outdoor unit 3100, and an outdoor unit fan 3102 provided on one side of the outdoor unit main body 3101 to discharge heat-exchanged air.

The indoor unit 3200 may include an indoor unit main body 3201 that forms an exterior of the indoor unit 3200, an indoor unit discharge opening 3202 provided on a front surface of the indoor unit main body 3201 to discharge heat-exchanged air, and the user interface panel 3220 for receiving an operation command for the air conditioner 3000-2 from the user.

The air conditioner according to FIG. 18 may include a power conversion device for generating a DC voltage, and the power conversion device may include a PWM controller. The PWM controller may perform overheating prevention, together with the temperature sensing circuit according to the disclosure.

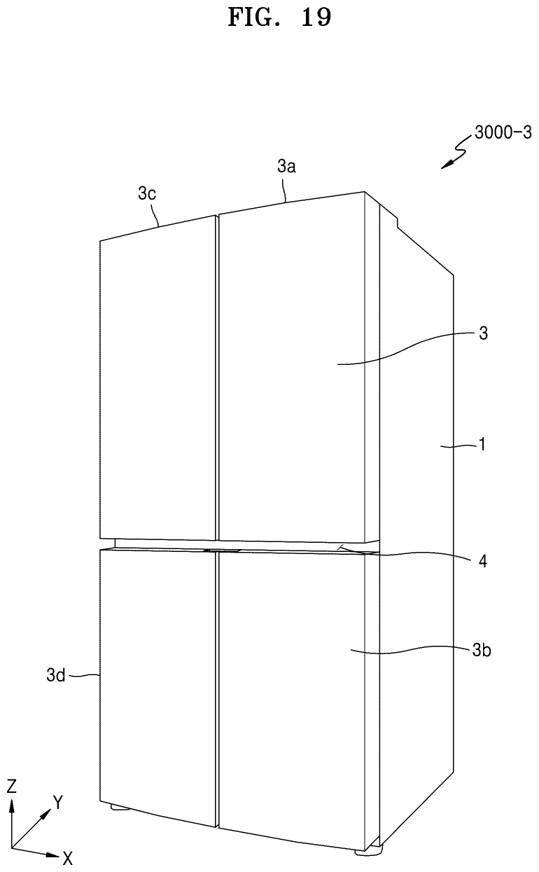

FIG. 19 is a diagram illustrating a refrigerator as a home appliance that includes a temperature sensing circuit for overheating prevention, according to an embodiment of the disclosure.

A refrigerator 3000-3 according to an embodiment of the disclosure may include a main body 1.

The main body 1 may include an inner casing, an outer casing arranged on an outer side of the inner casing, and an insulation material provided between the inner casing and the outer casing.

The “inner casing” may include a case, a plate, a panel, or a liner that forms a storage compartment. The inner casing may be formed as a single body, or may be formed by assembling a plurality of plates. The “outer casing” may form an exterior of the main body and may be coupled to an outer side of the inner casing such that the insulation material is arranged between the inner casing and the outer casing.

The “insulation material” may insulate between an interior of the storage compartment and an exterior of the storage compartment, such that a temperature inside the storage compartment may be maintained at a preset appropriate temperature without being affected by an external environment of the storage compartment. According to an embodiment, the insulation material may include a foam insulation material. After the inner casing and the outer casing are fixed with a jig or the like, the foam insulation material may be shaped by injecting a urethane foam, in which polyurethane and a foaming agent are mixed, into a space between the inner casing and the outer casing, and then causing the urethane foam to foam.

According to an embodiment, the insulation material may further include a vacuum insulation material in addition to the foam insulation material, or the insulation material may consist only of a vacuum insulation material instead of the foam insulation material. The vacuum insulation material may include a core material and an envelope material that accommodates the core material and seals an interior thereof to a vacuum or a pressure close to a vacuum. The vacuum insulation material may further include an adsorbent that adsorbs gas and moisture to stably maintain a vacuum state. However, the insulation material is not limited to the above-described foam insulation material or vacuum insulation material, and may include various materials that may be used for thermal insulation.

The refrigerator 3000-3 according to an embodiment of the disclosure may include a cold air supply device arranged to supply cold air to the storage compartment.

The “cold air supply device” may include a machine, an apparatus, or an electronic device capable of generating cold air and guiding the cold air to cool a storage compartment, and/or a system with a combination thereof.

According to an embodiment, the cold air supply device may generate cold air via a refrigeration cycle that includes processes of compression, condensation, expansion, and evaporation of a refrigerant. To this end, the cold air supply device may include a compressor, a condenser, an expansion device, and an evaporator that are capable of driving the refrigeration cycle.

The refrigerator 3000-3 according to an embodiment of the disclosure may include a machine compartment arranged such that at least some components belonging to the cold air supply device are arranged therein.

The “machine compartment” may be arranged to be partitioned and insulated from the storage compartment to prevent heat generated by components arranged in the machine compartment from being transferred to the storage compartment. The interior of the machine compartment may be configured to communicate with an exterior of the main body so as to dissipate heat from the components arranged inside the machine compartment.

The refrigerator 3000-3 is a type of home appliance that supplies cold air generated by the compressor of the cold air supply device, to the storage compartment, thereby enabling various foods to be preserved fresh for an extended period. In addition to this extended-period preservation function, various functions have been added to the refrigerator 3000-3, and representative functions include a communication function that enables configuration of an IoT network, a function that enables output of an audio via a speaker mounted in the refrigerator 3000-3, and the like.

Referring to FIG. 19, the refrigerator 3000-3 according to an embodiment of the disclosure may include doors 3a, 3b, 3c, and 3d for opening and closing the main body 1 and the storage compartment.

The refrigerator 3000-3, according to an embodiment of the disclosure, may include a door 3 configured to open and close an open side of the storage compartment.

Although the refrigerator 3000-3 according to FIG. 19 is illustrated with four doors 3, the number of doors 3 is not limited thereto, and for example, the upper door 3a and the lower door 3b on the right side of the refrigerator 3000-3 may be configured as a single door, and the upper door 3c and the lower door 3d on the left side of the refrigerator 3000-3 may be configured as a single door. In addition, the refrigerator 3000-3 may have more or fewer than four doors. In addition, the positions of the doors 3 may be variously changed. Depending on the arrangement of the doors 3 and the storage compartment, the refrigerator 3000-3 may be a French door-type refrigerator or a side-by-side-type refrigerator. Between the plurality of doors 3a, 3b, 3c, and 3d, there may exist a handle area 4, which is a clearance space into which a user may insert a hand to open or close the door 3.

The door 3 may be configured to seal the storage compartment when the door 3 is closed. Similar to the main body 1, the door 3 may include an insulation material to insulate the storage compartment when the door 3 is closed.

The refrigerator 3000-3 according to FIG. 19 may include a power conversion device for generating a DC voltage, and the power conversion device may include a PWM controller. The PWM controller may perform prevention of overheating in the refrigerator 3000-3, together with the temperature sensing circuit according to the disclosure.

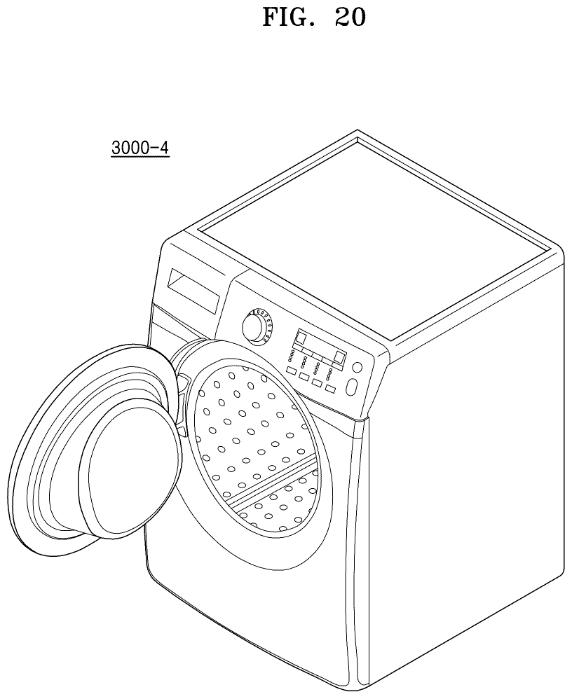

FIG. 20 is a diagram illustrating a washing machine as a home appliance that includes a temperature sensing circuit for overheating prevention, according to an embodiment of the disclosure.

A washing machine 3000-4 according to an embodiment of the disclosure is a home appliance used for the purpose of washing clothes and, when necessary, dehydrating them. The washing machine 3000-4, similar to the foregoing examples, may include a power conversion device for generating a DC voltage, and the power conversion device may include a PWM controller. The PWM controller may perform prevention of overheating in the washing machine 3000-4, together with the temperature sensing circuit according to the disclosure.

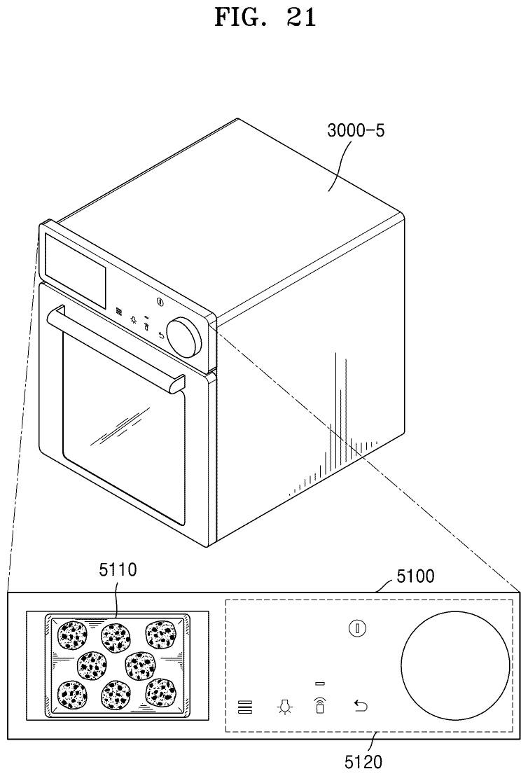

FIG. 21 is a diagram illustrating an electric oven as a home appliance that includes a temperature sensing circuit for overheating prevention, according to an embodiment of the disclosure.

An electric oven 3000-5, as a home appliance according to an embodiment of the disclosure, may include a user interface panel 5100. The user interface panel 5100 may include a display, serving as an output interface 5110, capable of showing an internal state from an exterior, and an input interface 5120 capable of delivering a user's command to the electric oven 3000-5.

The electric oven 3000-5, similar to the foregoing examples, may include a power conversion device for generating a DC voltage, and the power conversion device may include a PWM controller. The PWM controller may perform prevention of overheating in the electric oven 3000-5, together with the temperature sensing circuit according to the disclosure.

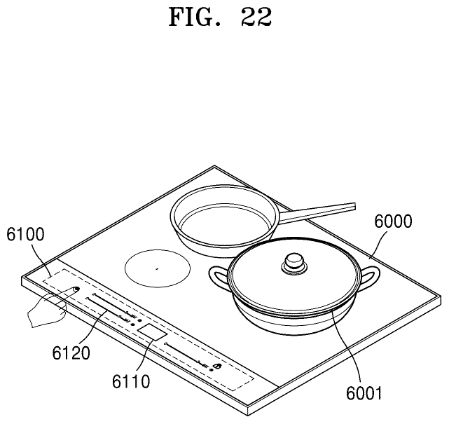

FIG. 22 is a diagram illustrating an induction cooking apparatus as a home appliance that includes a temperature sensing circuit for overheating prevention, according to an embodiment of the disclosure.

Referring to FIG. 22, an induction cooking apparatus 6000, as a home appliance according to an embodiment of the disclosure, may also be referred to as induction heating apparatus or an induction apparatus.

The induction cooking apparatus 6000 according to an embodiment of the disclosure may be a device that wirelessly transmits, by using electromagnetic induction, power to an object to be heated (e.g., a cooking vessel 6001) placed on a top plate. The induction cooking apparatus 6000 may include a working coil that generates a magnetic field for inductively heating the cooking vessel 6001.

Generating a magnetic field by the working coil may mean transmitting power by using a magnetic field induced in an induction heating (IH) metal (e.g., an iron component) via a magnetic induction method. For example, the induction apparatus 6000 may cause eddy currents to be generated in the cooking vessel 6001 by causing current to flow through the working coil, thereby forming a magnetic field.

According to an embodiment of the disclosure, the induction cooking apparatus 6000 may display, via a user interface panel 6100, information associated with the cooking vessel 6001. For example, when the cooking vessel 6001 is detected, the induction cooking apparatus 6000 may display identification information about the cooking vessel 6001 and position information about the cooking vessel 6001, on an output interface 6110 included in the user interface panel 6100. In addition, the induction cooking apparatus 6000 may deliver a user command to a processor of the induction cooking apparatus 6000 via an input interface 6120 included in the user interface panel 6100.

The induction cooking apparatus 6000, similar to the foregoing examples, may include a power conversion device for generating a DC voltage, and the power conversion device may include a PWM controller. The PWM controller may perform prevention of overheating in the induction cooking apparatus 6000, together with the temperature sensing circuit according to the disclosure.

In the home appliance according to an embodiment, the determining, by the PWM controller, of whether the overheating has occurred may include determining, in response to the voltage between the first point and the ground being greater than a predetermined threshold voltage, that the overheating has occurred.

In the home appliance according to an embodiment, the PWM controller may determine whether the overheating has occurred, and in response to determining that the overheating has occurred, cut off a gate output from the PWM controller to the switch.

In the home appliance according to an embodiment, the PWM controller may, in response to a voltage greater than the predetermined threshold voltage being input to an input allocated for performing an overheating protection function of the PWM controller, cut off the gate output from the PWM controller to the switch.

In the home appliance according to an embodiment, the first temperature sensor may be a PTC thermistor having a resistance value that increases as a sensed temperature increases.

The home appliance according to an embodiment may further include a second temperature sensor arranged between the first point and the at least one divider resistor, wherein a resistance of the second temperature sensor changes according to a temperature.

In the home appliance according to an embodiment, the second temperature sensor may be an NTC thermistor having a resistance value that decreases as a sensed temperature increases.

In the home appliance according to an embodiment, the first temperature sensor may be arranged between the first point and the ground, and the second temperature sensor may be arranged between the first point and a positive (+) terminal of the DC link capacitor.

The home appliance according to an embodiment may further include a processor configured to receive an output of a first comparator and an output of a second comparator, wherein the first comparator has, as inputs, a voltage across the first temperature sensor and the ground, and the predetermined threshold voltage, and the second comparator has, as inputs, a voltage across the second temperature sensor, and a predetermined second threshold voltage for determining, by the second temperature sensor, overheating. In the home appliance according to an embodiment, the processor may determine, based on the output of the first comparator and the output of the second comparator, whether a position of an overheating occurrence corresponds to the first temperature sensor or corresponds to the second temperature sensor.

The home appliance according to an embodiment may further include a display, and the processor may control the display to display at least one of overheating occurrence positions corresponding to the first temperature sensor and the second temperature sensor, based on at least one of the output of the first comparator and the output of the second comparator.

The home appliance according to an embodiment may further include a third temperature sensor connected in series to the first temperature sensor and configured to, together with the first temperature sensor, divide the voltage across the DC link capacitor, wherein a resistance of the third temperature sensor changes according to a temperature.

In the home appliance according to an embodiment, the third temperature sensor may be arranged between the first temperature sensor and the ground.

The home appliance according to an embodiment may further include a processor configured to receive an output of a first comparator and an output of a third comparator, wherein the first comparator has, as an input, a voltage across the first temperature sensor, and the third comparator has, as an input, a voltage across the third temperature sensor, and the processor may determine, based on the output of the first comparator and the output of the third comparator, whether a position of an overheating occurrence corresponds to the first temperature sensor or corresponds to the third temperature sensor.

The home appliance according to an embodiment may further include a display, and the processor may control the display to display at least one of overheating occurrence positions corresponding to the first temperature sensor and the third temperature sensor, based on at least one of the output of the first comparator and the output of the third comparator.

In the home appliance according to an embodiment, the first temperature sensor may be an NTC thermistor having a resistance value that decreases as a sensed temperature increases.

In the home appliance according to an embodiment, the at least one divider resistor may be arranged between the first point and the ground, and the first temperature sensor may be arranged between the first point and a positive (+) terminal of the DC link capacitor.

In the home appliance according to an embodiment, the determining, by the PWM controller, of whether the overheating has occurred may include determining, in response to the voltage between the first point and the ground being greater than a predetermined threshold voltage, that the overheating has occurred.

The home appliance according to an embodiment may further include a third temperature sensor connected in parallel to the first temperature sensor and having a resistance value that decreases as a sensed temperature increases.

A method of preventing overheating by using a temperature sensor in a home appliance, according to an embodiment of the disclosure, may include generating a DC voltage by rectifying an AC input voltage, and generating, from the generated DC voltage, a DC voltage smoothed by a DC link capacitor. The method of preventing overheating by a temperature sensor in a home appliance, according to an embodiment of the disclosure, may include sensing, by a PWM controller, from a temperature sensing circuit that includes a divider resistor for dividing the smoothed DC voltage and the temperature sensor, a voltage corresponding to a change in a resistance of the temperature sensor according to a change in a temperature in a vicinity of the temperature sensor, and in response to a magnitude of the sensed voltage reaching a predetermined threshold voltage, cutting off, by the PWM controller, driving of a switch for overheating prevention.

In an embodiment, the temperature sensor may be a PTC thermistor or an NTC thermistor.

A computer-readable storage medium capable of executing a method of preventing overheating by using a temperature sensor in a home appliance, according to an embodiment of the disclosure, may have stored therein one or more programs including instructions capable of executing generating a DC voltage by rectifying an AC input voltage, generating, from the generated DC voltage, a DC voltage smoothed by a DC link capacitor, sensing, by a PWM controller, from a temperature sensing circuit that includes a divider resistor for dividing the smoothed DC voltage and the temperature sensor, a voltage corresponding to a change in a resistance of the temperature sensor according to a change in a temperature in a vicinity of the temperature sensor, and in response to a magnitude of the sensed voltage reaching a predetermined threshold voltage, cutting off, by the PWM controller, driving of a switch for overheating prevention.

A method according to an embodiment of the disclosure may be embodied as program commands executable by various computer devices, and recorded on a computer-readable medium. The computer-readable medium may include program commands, data files, data structures, or the like separately or in combinations. The program commands to be recorded on the medium may be specially designed and configured for the disclosure or may be well-known to and be usable by those skilled in the art of computer software. Examples of the computer-readable recording medium include magnetic media such as hard disks, floppy disks, or magnetic tapes, optical media such as a compact disc read-only memory (CD-ROM) or a digital versatile disc (DVD), magneto-optical media such as a floptical disk, and hardware devices such as ROM, RAM, or flash memory, which are specially configured to store and execute program instructions. Examples of program instructions include not only machine code, such as code made by a compiler, but also high-level language code that is executable by a computer by using an interpreter or the like.

Some embodiments of the disclosure may be implemented as a recording medium including computer-readable instructions such as a computer-executable program module. The computer-readable medium may be any available medium which is accessible by a computer, and may include a volatile or non-volatile medium and a removable or non-removable medium. Also, the computer-readable medium may include a computer storage medium and a communication medium. The computer storage media include both volatile and non-volatile, removable and non-removable media implemented in any method or technique for storing information such as computer-readable instructions, data structures, program modules or other data. The communication media typically include computer-readable instructions, data structures, program modules, other data of a modulated data signal, or other transmission mechanisms, and examples thereof include an arbitrary information transmission medium. Also, some embodiments of the disclosure may be implemented as a computer program or a computer program product including computer-executable instructions such as a computer program executed by a computer.

A machine-readable storage medium may be provided in the form of a non-transitory storage medium. Here, the term ‘non-transitory storage medium’ refers to a tangible device and does not include a signal (e.g., an electromagnetic wave), and the term ‘non-transitory storage medium’ does not distinguish between a case where data is stored in a storage medium semi-permanently and a case where data is stored temporarily. For example, the ‘non-transitory storage medium’ may include a buffer in which data is temporarily stored.

According to an embodiment, methods according to various embodiments disclosed herein may be included in a computer program product and then provided. The computer program product may be traded as commodities between sellers and buyers. The computer program product may be distributed in the form of a machine-readable storage medium (e.g., a CD-ROM), or may be distributed online (e.g., downloaded or uploaded) through an application store or directly between two user devices (e.g., smart phones). In a case of online distribution, at least a portion of the computer program product (e.g., a downloadable app) may be temporarily stored in a machine-readable storage medium such as a manufacturer's server, an application store's server, or memory of a relay server.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A home appliance comprising:
a direct current (DC) link capacitor configured to smooth an alternating current input voltage;
at least one divider resistor configured to divide a voltage across the DC link capacitor;
a first temperature sensor connected in series to the at least one divider resistor, and configured to, together with the at least one divider resistor, divide the voltage across the DC link capacitor, wherein a resistance of the first temperature sensor changes according to a temperature;
a pulse-width modulation (PWM) controller configured to determine whether overheating has occurred, based on a change in a voltage between a first point and a ground, wherein the first point is a connection point between the at least one divider resistor and the first temperature sensor, and serves as an input to the PWM controller;
a switch whose switching is cut off by the PWM controller in response to the PWM controller determining that the overheating has occurred; and
a transformer configured to convert an output alternating current voltage generated according to a switching operation of the switch.

2. The home appliance of claim 1, wherein the determining, by the PWM controller, of whether the overheating has occurred comprises determining, in response to the voltage between the first point and the ground being greater than a predetermined threshold voltage, that the overheating has occurred.

3. The home appliance of claim 2, wherein the PWM controller is further configured to determine whether the overheating has occurred, and, in response to determining that the overheating has occurred, cut off a gate output from the PWM controller to the switch.

4. The home appliance of claim 3, wherein the PWM controller is further configured to, in response to a voltage greater than the predetermined threshold voltage being input to an input allocated for performing an overheating protection function of the PWM controller, cut off the gate output from the PWM controller to the switch.

5. The home appliance of claim 1, wherein the first temperature sensor is a positive temperature coefficient (PTC) thermistor having a resistance value that increases as a sensed temperature increases.

6. The home appliance of claim 1, further comprising:
a second temperature sensor arranged between the first point and the at least one divider resistor,
wherein a resistance of the second temperature sensor changes according to a temperature.

7. The home appliance of claim 6, wherein the second temperature sensor is a negative temperature coefficient (NTC) thermistor having a resistance value that decreases as a sensed temperature increases.

8. The home appliance of claim 6,
wherein the first temperature sensor is arranged between the first point and the ground, and
wherein the second temperature sensor is arranged between the first point and a positive (+) terminal of the DC link capacitor.

9. The home appliance of claim 6, further comprising:
a processor configured to receive an output of a first comparator and an output of a second comparator,
wherein the first comparator has, as inputs, a voltage across the first temperature sensor and the ground, and a predetermined threshold voltage, and the second comparator has, as inputs, a voltage across the second temperature sensor, and a predetermined second threshold voltage for determining, by the second temperature sensor, overheating, and
wherein the processor is further configured to determine, based on the output of the first comparator and the output of the second comparator, whether a position of the overheating occurrence corresponds to the first temperature sensor or corresponds to the second temperature sensor.

10. The home appliance of claim 9, further comprising:
a display, wherein the processor is further configured to control the display to display at least one of overheating occurrence positions corresponding to the first temperature sensor and the second temperature sensor, based on at least one of the output of the first comparator and the output of the second comparator.

11. The home appliance of claim 1, further comprising:
a third temperature sensor connected in series to the first temperature sensor and configured to, together with the first temperature sensor, divide the voltage across the DC link capacitor,
wherein a resistance of the third temperature sensor changes according to a temperature.

12. The home appliance of claim 11, wherein the third temperature sensor is arranged between the first temperature sensor and the ground.

13. The home appliance of claim 12, further comprising:
a processor configured to receive an output of a first comparator and an output of a third comparator,
wherein the first comparator has, as an input, a voltage across the first temperature sensor, and the third comparator has, as an input, a voltage across the third temperature sensor, and
wherein the processor is further configured to determine, based on the output of the first comparator and the output of the third comparator, whether a position of the overheating occurrence corresponds to the first temperature sensor or corresponds to the third temperature sensor.

14. The home appliance of claim 1,
wherein the first temperature sensor is an NTC thermistor having a resistance value that decreases as a sensed temperature increases,
wherein the at least one divider resistor is arranged between the first point and the ground, and
wherein the first temperature sensor is arranged between the first point and a positive (+) terminal of the DC link capacitor.

15. The home appliance of claim 14, wherein the determining, by the PWM controller, of whether the overheating has occurred comprises determining, in response to the voltage between the first point and the ground being greater than a predetermined threshold voltage, that the overheating has occurred.

16. The home appliance of claim 2, wherein the first temperature sensor is a positive temperature coefficient (PTC) thermistor having a resistance value that increases as a sensed temperature increases.

17. The home appliance of claim 3, wherein the first temperature sensor is a positive temperature coefficient (PTC) thermistor having a resistance value that increases as a sensed temperature increases.

18. The home appliance of claim 4, wherein the first temperature sensor is a positive temperature coefficient (PTC) thermistor having a resistance value that increases as a sensed temperature increases.

19. The home appliance of claim 2, further comprising:
a second temperature sensor arranged between the first point and the at least one divider resistor,
wherein a resistance of the second temperature sensor changes according to a temperature.

20. The home appliance of claim 3, further comprising:
a second temperature sensor arranged between the first point and the at least one divider resistor,
wherein a resistance of the second temperature sensor changes according to a temperature.
